(19) United States
(12) Patent Application Publication
(10) Pub. No.: US 2016/0254812 A1
(43) Pub. Date: Sep. 1, 2016

(54) APPARATUS FOR CALIBRATING OFF-CHIP DRIVER/ON-DIE TERMINATION CIRCUITS

(71) Applicant: SanDisk Technologies Inc., Plano, TX (US)

(72) Inventor: Hitoshi Miwa, Kamakura (JP)

(73) Assignee: SANDISK TECHNOLOGIES INC., Plano, TX (US)

(21) Appl. No.: 14/632,179

(22) Filed: Feb. 26, 2015

(51) Int. Cl. H03K 19/00

(52) U.S. Cl. CPC H03K 19/0005

(57) ABSTRACT

An impedance calibration circuit is provided for off-chip driver/on-die termination circuits. The impedance calibration circuit includes a first circuit that includes first PMOS transistors coupled in parallel between a power supply terminal and a first output terminal, second PMOS transistors coupled in parallel between the power supply terminal and a second output terminal, first NMOS transistors coupled in parallel between the second output terminal and a GROUND terminal, a third PMOS transistor coupled in parallel with the first PMOS transistors between a power supply terminal and a first output terminal, and a second NMOS transistor coupled in parallel with the first NMOS transistors between the second output terminal and a GROUND terminal.

### BACKGROUND

The present technology relates to non-volatile memory.

Solid-state memory capable of nonvolatile storage of charge, particularly in the form of EEPROM and flash EEPROM packaged as a small form factor card, has become the storage of choice in a variety of mobile and handheld devices, notably information appliances and consumer electronics products. Unlike RAM (random access memory) that is also solid-state memory, flash memory is non-volatile, and retaining its stored data even after power is turned off. Also, unlike ROM (read only memory), flash memory is rewritable similar to a disk storage device. Despite the higher cost, flash memory is increasingly being used in mass storage applications. More recently, flash memory in the form of solid-state disks (SSD) is beginning to replace hard disks in portable computers as well as in fixed location installations.

In flash memory devices, a memory cell can include a floating gate that is positioned above and insulated from a channel region in a semiconductor substrate, in a two-dimensional (2D) NAND configuration. The floating gate is positioned between source and drain regions. A control gate is provided over and insulated from the floating gate. The threshold voltage (Vth) of the transistor thus formed is controlled by the amount of charge that is retained on the floating gate. That is, the minimum amount of voltage that must be applied to the control gate before the transistor is turned on to permit conduction between its source and drain is controlled by the level of charge on the floating gate. A memory cell can have a floating gate that is used to store two or more ranges of charges, where each range represents a data state.

Moreover, ultra high density storage devices have been proposed using a three-dimensional (3D) stacked memory structure which is formed from an array of alternating conductive and dielectric layers. One example is the Bit Cost Scalable (BiCS) architecture. A memory hole is drilled in the layers, and a NAND string is formed by filling the memory hole with appropriate materials. A straight NAND string extends in one memory hole, while a pipe- or U-shaped NAND string (P-BiCS) includes a pair of vertical columns of memory cells which extend in two memory holes and which are joined by a bottom back gate. Control gates of the memory cells are provided by the conductive layers.

High performance integrated-circuit memory devices typically have multiple die or chips controlled by a memory controller. Each die contains a memory array with peripheral circuits. At any one time, many of these multiple die may be involved in various memory operations including input or output operations with the memory controller. For example, in enterprise SSD and Client SSD the input/output (I/O) requirements are demanding. In some instances, 8 to 16 die are stacked on the same I/O channel and they are operating at 200 MHz (DDR2) speed with reduced power.

One issue has to do with the proper termination of the I/O channel. At the microwave operating frequencies, the I/O channel behaves like a transmission line and improper impedance match or termination will lead to reflections. The reflections will degrade the transmission speed. Accordingly, memory devices typically include off-chip-driver (OCD) and on-die termination (ODT) circuits for driving and terminating I/O channels.

However, as process geometries shrink, many design and process challenges are presented for OCD and ODT circuits. These challenges include calibration errors and circuit non-linearities.

### BRIEF DESCRIPTION OF THE DRAWINGS

FIG. 1 is a block diagram of a host and memory device.

FIG. 2 is a block diagram of an I/O channel between a memory die and a memory controller.

FIG. 3 is a block diagram of an embodiment of an OCD/ODT circuit and an impedance calibration circuit.

FIG. 4A is a circuit diagram of a previously known OCD circuit.

FIG. 4B is a circuit diagram of a previously known ODT circuit.

FIG. 4C is a circuit diagram of a previously known impedance calibration circuit for use with the OCD circuit of FIG. 4A.

FIG. 4D is a circuit diagram of a previously known impedance calibration circuit for use with the ODT circuit of FIG. 4B.

FIGS. 5A-5C are block diagrams of embodiments of impedance calibration circuits.

FIG. 6A is a diagram of an example calibration process of the previously known impedance calibration circuit of FIG. 4C,

FIG. 6B is a diagram of an example calibration process of the impedance calibration circuit of FIG. 5A.

FIG. 7A is a diagram of an example pull-up calibration process of the impedance calibration circuit of FIG. 5A.

FIG. 7B is a diagram of an example pull-down calibration process of the previously known impedance calibration circuit of FIG. 4C.

FIG. 7C is a diagram of an example pull-down calibration process of the impedance calibration circuit of FIG. 5A.

FIG. 8A is a diagram of an example pull-up impedance calibration process for the OCD replica circuit of FIG. 5B.

FIG. 8B is a diagram of an example pull-down impedance calibration for the OCD replica circuit of FIG. 5B.

FIG. 9A is a block diagram of another embodiment of an impedance calibration circuit.

FIG. 9B is a block diagram of an example embodiment of one of the ODT replica circuits of FIG. 9A.

FIG. 10 is an example look up table for use by the replica selection circuit of FIG. 9A.

FIG. 11A-11B depict currents flowing through the pull-up ODT structure and the pull-down ODT structure of ODT circuits.

FIG. 12A is a block diagram of another embodiment of an impedance calibration circuit.

FIG. 12B is a block diagram of an embodiment of an ODT replica circuit of FIG. 12A.

### DETAILED DESCRIPTION

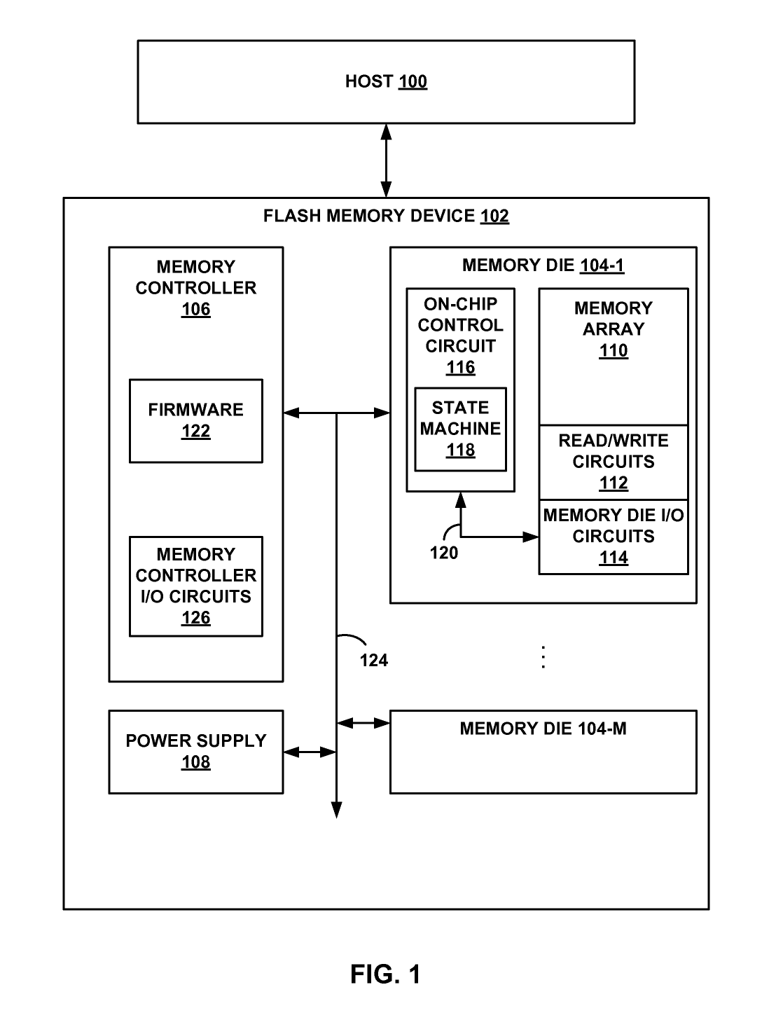

FIG. 1 illustrates a host 100 in communication with a memory device 102. Host 100 typically sends data to be stored in memory device 102 or retrieves data by reading memory device 102. Memory device 102 includes one or more memory die 104 managed by a memory controller 106. Memory controller 106 is typically implemented as another chip with CMOS circuit elements. FIG. 1 shows, for example the memory device having M die, such as memory die 104-1, . . . , memory die 104-M. Memory device 102 is powered by a power supply 108 that has a predetermined maximum capacity.

Each memory die 104-1, . . . , 104-M includes a memory array 110 of memory cells. In an embodiment, the memory cells are flash EEPROM memory cells arranged in a NAND architecture. In an embodiment, each memory cell is capable of being configured as a multi-level cell (MLC) for storing multiple bits of data, as well as capable of being configured as a single-level cell (SLC) for storing 1 bit of data. Each memory die 104-1, . . . , 104-M also includes peripheral circuits such as row and column decoders (not shown), read/write circuits 112 and die I/O circuits 114. An on-chip control circuit 116 controls low-level memory operations of each die. On-chip control circuit 116 is a controller that cooperates with the peripheral circuits to perform memory operations on memory array 110. On-chip control circuit 116 includes a state machine 118 to provide die or chip level control of low-level memory operations via an internal bus 120 for carrying control signals, data and addresses.

In many implementations, host 100 communicates and interacts with each of memory die 104-1, . . . , 104-M via memory controller 106. Memory controller 106 cooperates with memory die 104-1, . . . , 104-M and controls and manages higher level memory operations. Memory controller include firmware 122, which provides codes to implement the functions of memory controller 106.

For example, in a host write, host 100 sends data to be written to memory array 110 in logical sectors allocated from a file system of the host's operating system. A memory block management system implemented in the controller stages the sectors and maps and stores them to the physical structure of the memory array.

To improve read and program performance, multiple charge storage elements or memory transistors in an array are read or programmed in parallel. Thus, a “page” of memory elements are read or programmed together. In existing memory architectures, a row typically contains several interleaved pages or it may constitute one page. Preferably, all memory elements of a page are read or programmed together.

A memory device bus 124 provides communications and power between memory controller 106, power supply 108 and memory die 104-1, . . . , 104-M. An I/O channel is established between memory controller 106 and each of memory die 104-1, . . . , 104-M via memory device bus 124 and internal bus 120. Each I/O channel has a controller I/O circuit 126 and one of I/O circuits 114 of memory die 104-1, . . . , 104-M as endpoints.

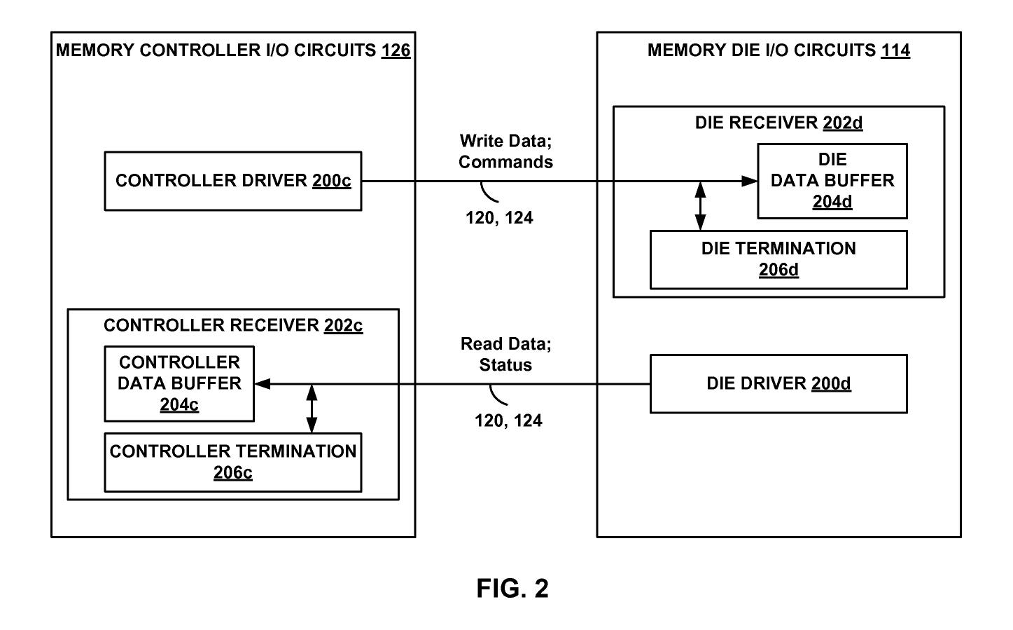

FIG. 2 illustrates an I/O channel established between a memory die (e.g., memory die 104-1) and memory controller 106. Memory die 104-1 includes Memory Die I/O circuits 114 and memory controller 106 includes Memory Controller I/O circuits 126. Memory die I/O circuits 114 and Memory Controller I/O circuits 126 each include a driver and a receiver. In particular, Memory Controller I/O circuits 126 include a controller driver 200c and a controller receiver 202c, which includes a controller data buffer 204c and a controller termination 206c. Memory die I/O circuits 114 include a die driver 200d and a die receiver 202d, which includes a die data buffer 204d and a die termination 206d.

When memory controller 106 sends data or commands to memory die 104-1, such as in a write operation, the data are driven by controller driver 200c via device bus 120, 124 to die receiver 202d. When memory die 104-1 sends data or status to memory controller 106, such as in a read operation, the data are driven by die driver 200d via device bus 120, 124 to controller receiver 202c.

As previously mentioned, memory devices typically include OCD circuits for driving I/O channels and ODT circuits for terminating I/O channels. In an embodiment, controller driver 200c and die driver 200d each include OCD circuits for driving device bus 120, 124, and controller termination 206c and die termination 206d each include ODT circuits for terminating device bus 120, 124.

As previously mentioned, at microwave operating frequencies, the I/O channel of a memory device behaves like a transmission line, and improper impedance match or termination will lead to reflections, which degrade transmission speed. To reduce such reflections, OCD and ODT circuits match impedance characteristics of the I/O channel to which they are connected. In addition, to account for variations in process, power supply voltage and temperature (PVT), OCD and ODT circuits typically have an impedance adjustment function, and an impedance control circuit provides control signals to adjust the impedance of the OCD and ODT circuits.

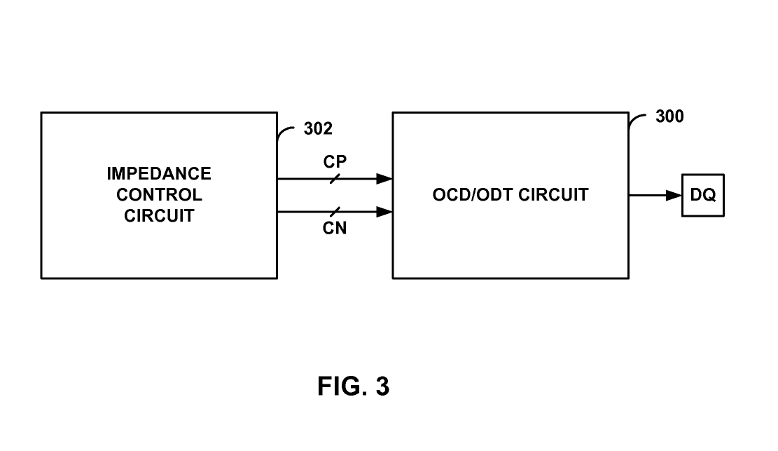

FIG. 3 is a block diagram of an embodiment of an OCD/ODT circuit 300 and an impedance calibration circuit 302. OCD/ODT circuit 300 is coupled to an I/O channel via an I/O terminal DQ, and receives first control signals CP and second control signals CN from impedance calibration circuit 302. First control signals CP and second control signals CN each include multiple control signals (e.g., binary bits). As described in more detail below, impedance calibration circuit 302 includes a replica OCD/ODT circuit that includes a replica of OCD/ODT circuit 300.

As also described in more detail below, during a calibration process, such as a ZQ calibration process, first control signals CP and second control signals CN are adjusted until an impedance of the replica OCD/ODT circuit matches an impedance of an external reference resistor, and then the adjusted values of first control signals CP and second control signals CN are used to set an impedance of OCD/ODT circuit 300. In this regard, the impedance of OCD/ODT circuit 300 matches an impedance proportional to the impedance of the external reference resistor. The ZQ calibration process may be used to reduce OCD/ODT circuit impedance error due to variations in process, power supply voltage and temperature.

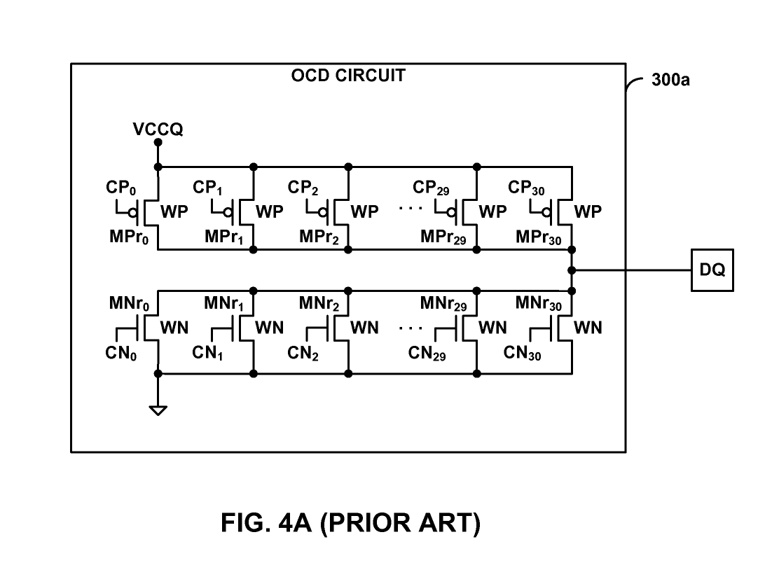

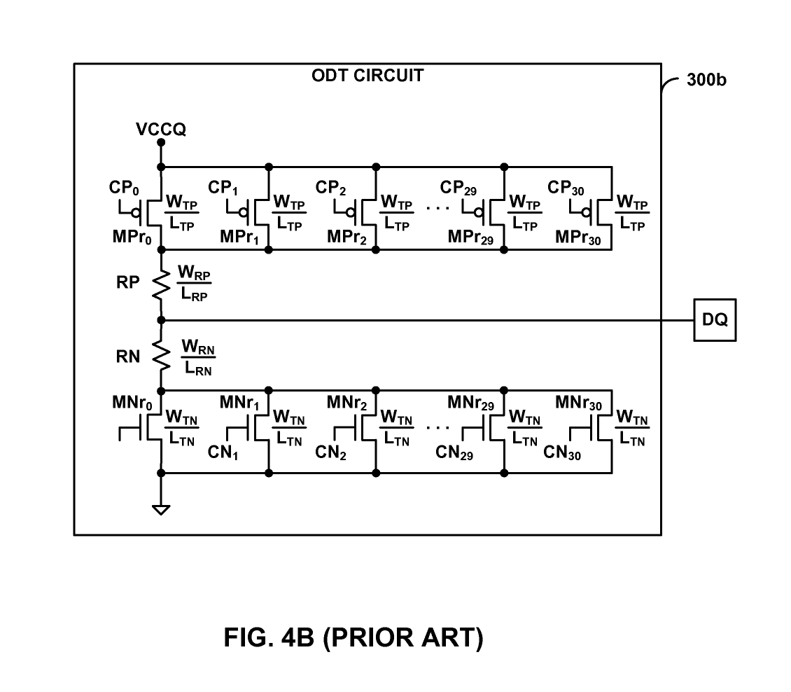

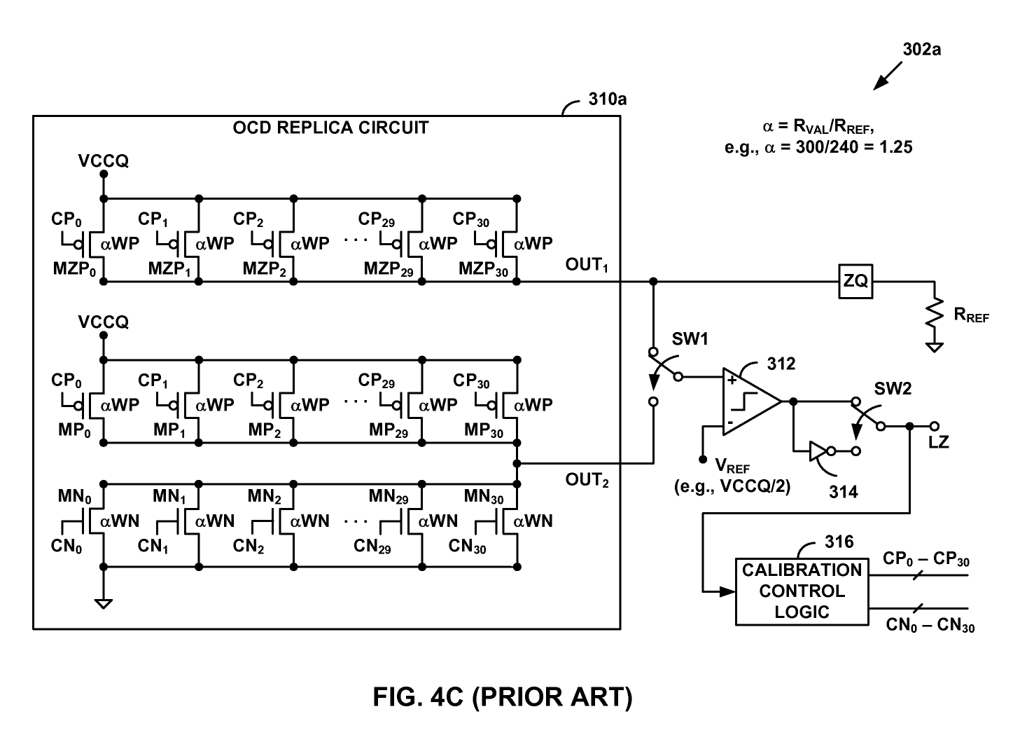

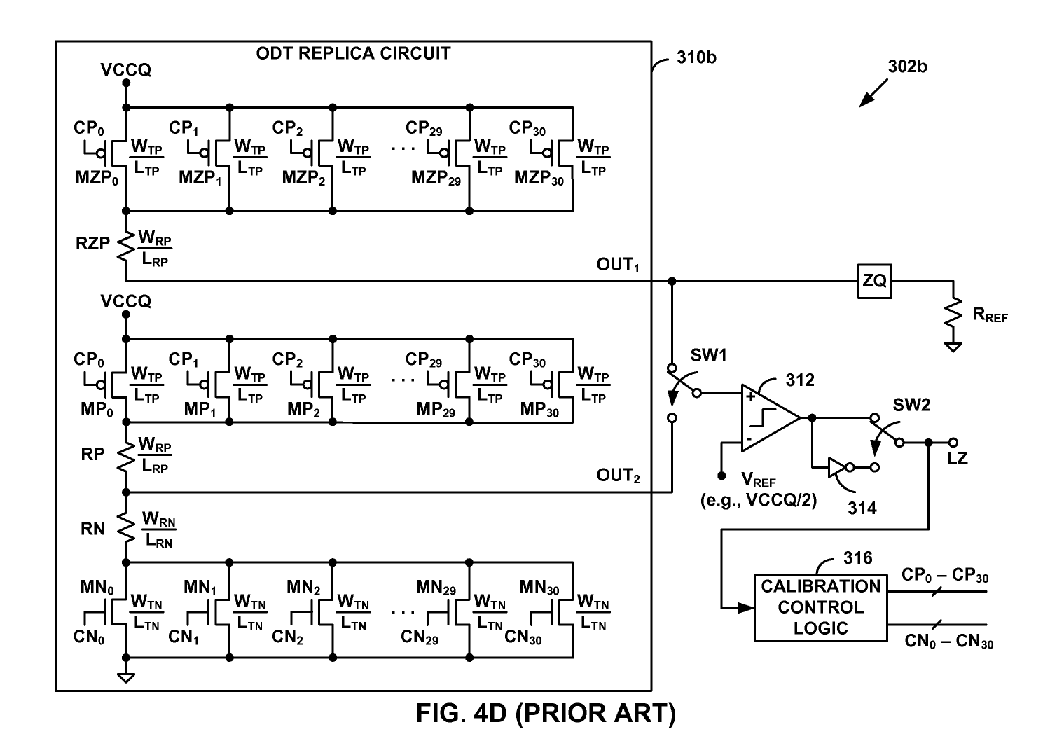

FIG. 4A illustrates a circuit diagram of a previously known OCD circuit 300a. OCD circuit 300a includes PMOS transistors MPr₀, MPr₁, . . . , MPr₃₀ and NMOS transistors MNr₀, MNr₁, . . . , MNr₃₀. Persons of ordinary skill in the art will understand that OCD circuits may include more or fewer than 31 PMOS transistors and NMOS transistors. PMOS transistors MPr₀, MPr₁, . . . , MPr₃₀ are coupled in parallel between a power supply VCCQ and an I/O terminal DQ, and NMOS transistors MNr₀, MNr₁, . . . , MNr₃₀ are coupled in parallel between I/O terminal DQ and GROUND.

Each of PMOS transistors MPr₀, MPr₁, . . . , MPr₃₀ has a width WP and has a gate terminal coupled to a corresponding one of first control signals CP₀, CP₁, . . . , CP₃₀, and each of NMOS transistors MNr₀, MNr₁, . . . , MNr₃₀ has a width WN and has a gate terminal coupled to a corresponding one of second control signals CN₀, CN₁, . . . , CN₃₀. First control signals CP₀, CP₁, . . . , CP₃₀ and second control signals CN₀, CN₁, . . . , CN₃₀ each include 31 control signals (e.g., binary bits). Persons of ordinary skill in the art will understand that control signals CP and CN each may include more or fewer than 31 controls signals.

FIG. 4B illustrates a circuit diagram of a previously known ODT circuit 300b. ODT circuit 300b includes PMOS transistors MPr₀, MPr₁, . . . , MPr₃₀, NMOS transistors MNr₀, MNr₁, . . . , MNr₃₀, first resistor RP and second resistor RN. Persons of ordinary skill in the art will understand that ODT circuits may include more or fewer than 3 PMOS transistors and NMOS transistors. PMOS transistors MPr₀, MPr₁, . . . , MPr₃₀ are coupled in parallel between a power supply VCCQ and a first terminal of first resistor RP, NMOS transistors MNr₀, MNr₁, . . . , MNr₃₀ are coupled in parallel between a first terminal of second resistor RN and GROUND, first resistor RP has a second terminal coupled to a second terminal of second resistor RN and to I/O terminal DQ.

In the embodiment of FIG. 4B, each of PMOS transistors MPr₀, MPr₁, . . . , MPr₃₀ has a width W_{TP}, a length L_{TP} and has a gate terminal coupled to a corresponding one of control signals CP₀, CP₁, . . . , CP₃₀, and each of NMOS transistors MNr₀, MNr₁, . . . , MNr₃₀ has a width W_{TN}, a length L_{TN} and has a gate terminal coupled to a corresponding one of control signals CN₀, CN₁, . . . , CN₃₀. Persons of ordinary skill in the art will understand that control signals CP and CN each may include more or fewer than 31 controls signals. First resistor RP has a width W_{RP} and a length L_{RP}, and second resistor RN has a width W_{RN} and a length L_{RN}.

PMOS transistors MPr₀, MPr₁, . . . , MPr₃₀ and first resistor RP are also referred to herein as the “pull-up ODT structure” of ODT circuit 300b, and NMOS transistors MNr₀, MNr₁, . . . , MNr₃₀ and second resistor RN are also referred to herein as the “pull-down ODT structure” of ODT circuit 300b.

FIG. 4C illustrates a circuit diagram of a previously known impedance calibration circuit 302a for use with OCD circuit 300a of FIG. 4A. Impedance calibration circuit 302a includes OCD replica circuit 310a, first switch SW1, comparator 312, inverter 314, second switch SW2, calibration control logic 316 and reference resistor R_{REF}. OCD replica circuit 310a has a first output terminal OUT₁ coupled to a first terminal of first switch SW1 and an impedance adjustment terminal ZQ, and a second output terminal OUT₂ coupled to a second terminal of first switch SW1. Reference resistor R_{REF} has a first terminal coupled to impedance adjustment terminal ZQ, and a second terminal coupled to GROUND. In an embodiment, reference resistor R_{REF} is 240 ohms, although other values may be used.

Comparator 312 has a first (non-inverting) input terminal coupled to a third terminal of first switch SW1, a second (inverting) input terminal coupled to a reference voltage V_{REF}, typically equal to VCCQ/2, and an output terminal coupled to a first terminal of second switch SW2 and an input terminal of inverter 314. Second switch SW2 has a second terminal coupled to an output terminal of inverter 314, and a third terminal LZ coupled to an input terminal of calibration control logic 316. Calibration control logic 316 provides first control signals CP₀, CP₁, . . . , CP₃₀, and second control signals CN₀, CN₁, . . . , CN₃₀.

OCD replica circuit 310a includes first PMOS transistors MZP₀, MZP₁, . . . , MZP₃₀, second PMOS transistors MP₀, MP₁, . . . , MP₃₀, and NMOS transistors MN₀, MN₁, . . . , MN₃₀. First PMOS transistors MZP₀, MZP₁, . . . , MZP₃₀ are coupled in parallel between a power supply VCCQ and first output terminal OUT₁, second PMOS transistors MP₀, MP₁, . . . , MP₃₀ are coupled in parallel between a power supply VCCQ and second output terminal OUT₂, and NMOS transistors MN₀, MN₁, . . . , MN₃₀ are coupled in parallel between second output terminal OUT₂ and GROUND. First output terminal OUT₁ provides an output of first PMOS transistors MZP₀, MZP₁, . . . , MZP₃₀, and second output terminal OUT₂ provides an output of second PMOS transistors MP₀, MP₁, . . . , MP₃₀ and NMOS transistors MN₀, MN₁, . . . , MN₃₀.

Each of first PMOS transistors MZP₀, MZP₁, . . . , MZP₃₀ and second PMOS transistors MP₀, MP₁, . . . , MP₃₀ has a width αWP and has a gate terminal coupled to a corresponding one of first control signals CP₀, CP₁, . . . , CP₃₀, and each of NMOS transistors MN₀, MN₁, . . . , MN₃₀ has a width αWN and has a gate terminal coupled to a corresponding one of second control signals CN₀, CN₁, . . . , CN₃₀, where α=R_{VA}L/R_{REF}, and where R_{VAL} is a nominal targeting impedance of OCD circuit 300a of FIG. 4A. In an example embodiment, R_{VAL}=300 ohms and reference resistor R_{REF}=240 ohms, and therefore α=1.25. Persons of ordinary skill in the art will understand that other values of R_{VAL}, R_{REF} and a may be used.

Calibration control logic 316 varies first control signals CP₀, CP₁, . . . , CP₃₀ and second control signals CN₀, CN₁, . . . , CN₃₀, controls first switch SW1 and second switch SW2, and receives as input the signal LZ. During a calibration process, sometimes referred to as “ZQ calibration,” impedance calibration circuit 302a implements a two-step calibration process. In a first calibration step, sometimes referred to as “pull-up calibration,” calibration control logic 316 configures first switch SW1 to connect first output terminal OUT₁ and impedance adjustment terminal ZQ to the non-inverting input terminal of comparator 312, and configures second switch to connect the non-inverted output of comparator 312 as the LZ signal input to calibration control logic 316. Comparator 312 compares the output of first PMOS transistors MZP₀, MZP₁, . . . , MZP₃₀, with VCCQ/2.

Calibration control logic 316 initially sets each of first control signals CP₀, CP₁, . . . , CP₃₀ HIGH, so all of first PMOS transistors MZP₀, MZP₁, . . . , MZP₃₀ are OFF, and first PMOS transistors MZP₀, MZP₁, . . . , MZP₃₀ have maximum impedance much greater than R_{REF}. As a result, the voltage level on impedance adjustment terminal ZQ is less than VCCQ/2, and the output of comparator 312 is LOW (e.g., 0). As a result, LZ=0. Calibration control logic 316 then successively sets individual ones of first control signals CP₀, CP₁, . . . , CP₃₀ LOW, thereby incrementally turning ON a corresponding one of first PMOS transistors MZP₀, MZP₁, . . . , MZP₃₀ step by step.

As each transistor turns ON, the composite resistance of first PMOS transistors MZP₀, MZP₁, . . . , MZP₃₀ decreases. As a result, the voltage level on impedance adjustment terminal ZQ increases. When the voltage level on impedance adjustment terminal ZQ exceeds VCCQ/2, the output of comparator 312 switches from LOW to HIGH (e.g., 0 to 1). As a result, LZ switches from 0 to 1, and at that point the impedance of first PMOS transistors MZP₀, MZP₁, . . . , MZP₃₀ matches the impedance of reference resistor R_{REF}. Calibration control logic 316 stores the values of first control signals CP₀, CP₁, . . . , CP₃₀ when LZ switches from 0 to 1 as CP_{match}.

In a second calibration step, sometimes referred to as “pull-down calibration,” calibration control logic 316 configures first switch SW1 to connect second output terminal OUT₂ to the non-inverting input terminal of comparator 312, and configures second switch SW2 to connect the output of inverter 314 as the LZ signal input to calibration control logic 316. Comparator 312 compares the output of second PMOS transistors MP₀, MP₁, . . . , MP₃₀ and NMOS transistors MN₀, MN₁, . . . , MN₃₀ with VCCQ/2. Calibration control logic 316 sets the values of first control signals CP₀, CP₁, . . . , CP₃₀ to CP_{match}. As a result, second PMOS transistors MP₀, MP₁, . . . , MP₃₀ have a impedance equal to the impedance of first PMOS transistors MZP₀, MZP₁, . . . , MZP₃₀ that matched reference resistor R_{REF} from the first calibration step.

Calibration control logic 316 initially sets each of second control signals CN₀, CN₁, . . . , CN₃₀ LOW, so all of NMOS transistors MN₀, MN₁, . . . , MN₃₀ are OFF, and NMOS transistors MN₀, MN₁, . . . , MN₃₀ have maximum impedance much greater than R_{REF}. As a result, the voltage level of second output terminal OUT₂ is greater than VCCQ/2, the output of comparator 312 is HIGH (e.g., 1), and the output of inverter 314 is LOW (e.g., 0). As a result, LZ=0. Calibration control logic 316 then successively sets individual ones of second control signals CN₀, CN₁, . . . , CN₃₀ HIGH, thereby turning ON a corresponding one of NMOS transistors MN₀, MN₁, . . . , MN₃₀.

As each transistor turns ON, the composite impedance of NMOS transistors MN₀, MN₁, . . . , MN₃₀ decreases. As a result, the voltage level of second output terminal OUT₂ decreases. When the voltage level of second output terminal OUT₂ falls below VCCQ/2, the output of comparator 312 switches from HIGH to LOW (e.g., 1 to 0), the output of inverter 314 switches from LOW to HIGH (e.g., 0 to 1). As a result, LZ switches from 0 to 1, and at that point the impedance of NMOS transistors MN₀, MN₁, . . . , MN₃₀ matches the impedance of second PMOS transistors MP₀, MP₁, . . . , MP₃₀. Calibration control logic 316 stores the values of second control signals CN₀, CN₁, . . . , CN₃₀ when LZ switches from 0 to 1 as CN_{match}.

The stored values CP_{match} of first control signals CP₀, CP₁, . . . , CP₃₀ and CN_{match} of second control signals CN₀, CN₁, . . . , CN₃₀ may then be used to set an output impedance of OCD circuit 300a of FIG. 4A. In particular, an output impedance of OCD circuit 300a matches the nominal targeting impedance R_{VAL}.

FIG. 4D illustrates a circuit diagram of a previously known impedance calibration circuit 302b for use with ODT circuit 300b of FIG. 4B. Impedance calibration circuit 302b includes OCD replica circuit 310b, first switch SW1, comparator 312, inverter 314, second switch SW2, calibration control logic 316 and reference resistor R_{REF}. OCD replica circuit 310b has a first output terminal OUT₁ coupled to a first terminal of first switch SW1 and an impedance adjustment terminal ZQ, and a second output terminal OUT₂ coupled to a second terminal of first switch SW1. Rreference resistor R_{REF} has a first terminal coupled to impedance adjustment terminal ZQ, and a second terminal coupled to GROUND. In an embodiment, reference resistor R_{REF} is 240 ohms, although other values may be used.

Comparator 312 has a first (non-inverting) input terminal coupled to a third terminal of first switch SW1, a second (inverting) input terminal coupled to reference voltage V_{REF}, and an output terminal coupled to a first terminal of second switch SW2 and an input terminal of inverter 314. Second switch SW2 has a second terminal coupled to an output terminal of inverter 314, and a third terminal LZ coupled to an input terminal of calibration control logic 316. Calibration control logic 316 provides first control signals CP₀, CP₁, . . . , CP₃₀, and second control signals CN₀, CN₁, . . . , CN₃₀.

OCD replica circuit 310b includes first PMOS transistors MZP₀, MZP₁, . . . , MZP₃₀, second PMOS transistors MP₀, MP₁, . . . , MP₃₀, NMOS transistors MN₀, MN₁, . . . , MN₃₀, first resistor RP, second resistor RN and third resistor RZP. First PMOS transistors MZP₀, MZP₁, . . . , MZP₃₀ are coupled in parallel between a power supply VCCQ and a first terminal of third resistor RZP, which has a second terminal coupled to first output terminal OUT₁. Second PMOS transistors MP₀, MP₁, . . . , MP₃₀ are coupled in parallel between a power supply VCCQ and a first terminal of first resistor RP, which has a second terminal coupled to second output terminal OUT₂. NMOS transistors MN₀, MN₁, . . . , MN₃₀ are coupled in parallel between GROUND and a first terminal of second resistor RN, which has a second terminal coupled to second output terminal OUT₂.

Each of first PMOS transistors MZP₀, MZP₁, . . . , MZP₃₀ and second PMOS transistors MP₀, MP₁, . . . , MP₃₀ has a width W_{TP} and a length L_{TP}, and has a gate terminal coupled to a corresponding one of first control signals CP₀, CP₁, . . . , CP₃₀. Each of NMOS transistors MN₀, MN₁, . . . , MN₃₀ has a width W_{TN} and a length L_{TN}, and has a gate terminal coupled to a corresponding one of second control signals CN₀, CN₁, . . . , CN₃₀. First resistor RP has a width W_{RP} and a length L_{RP}, second resistor RN has a width W_{RN} and a length L_{RN}, and third resistor RZP has a width W_{RP} and a length L_{RP}. During a ZQ calibration process, impedance calibration circuit 302b implements the two-step pull-up/pull-down calibration process described above with respect to impedance calibration circuit 302a of FIG. 4C.

As described above, a ZQ calibration process may be used with impedance calibration circuits 302a and 302b to reduce OCD/ODT circuit impedance error due to variations in process, power supply voltage and temperature. However, several problems exist with previously known impedance calibration circuits. First, in the ZQ calibration process described above, the OCD/ODT impedance is adjusted to a target impedance at a finite step size (e.g., the incremental impedance of each turned ON transistor). Therefore, the worst calibration error can be as large as the step size. To reduce the error, the step size needs to be smaller. However, reducing the step size results in a larger number of transistors and resistors, which detrimentally increases pin capacitance, layout area, number of signals and power consumption.

Second, if the OCD/ODT impedance is adjusted to the lowest value, but the lowest value is still higher than the target impedance, the impedance calibration function has to return a “fail” status to the user. This is because the lowest impedance can be unacceptably higher than the target impedance. But in some cases, the lowest impedance is close to the target impedance. If the difference between the lowest impedance and the target impedance is within the step size, we may not have to return a “fail” status to the user. So some “pass” status cases are lost. To avoid this, the lowest impedance needs to be low enough so that it is always lower than the target impedance. To achieve such low impedance, the OCD/ODT transistor size needs to be increased. However, increasing the transistor size detrimentally increases pin capacitance, layout area, and power consumption.

Third, the OCD/ODT impedance varies due to non-linearity of transistors in the OCD/ODT circuit. Such non-linearity is larger when the transistor Ids (drain-source current) is varied smaller. Then the smaller Ids transistor results in larger RON/R_{TT} error. To reduce the non-linearity, the transistor impedance needs to be low enough and the resistor impedance needs to be high enough. However, a low impedance transistor needs to have a large width and a high impedance resistor needs to have a large length. Such wide transistors and long resistors detrimentally results in increased pin capacitance, layout area and power consumption.

Technology is described which seeks to address these problems.

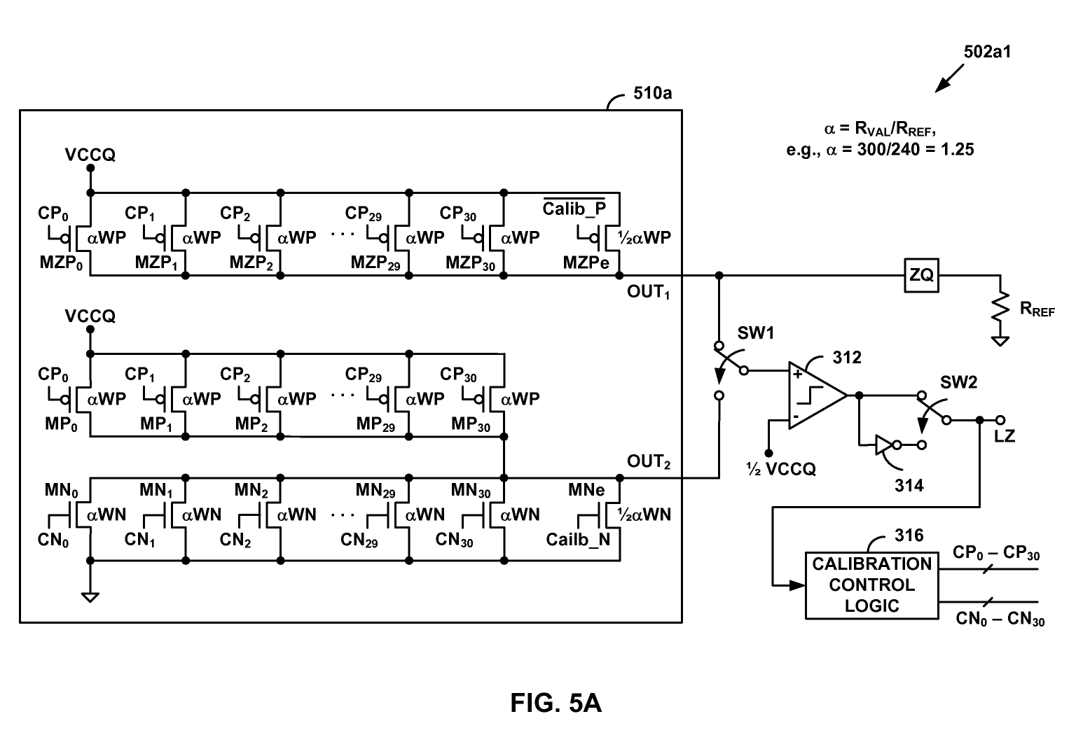

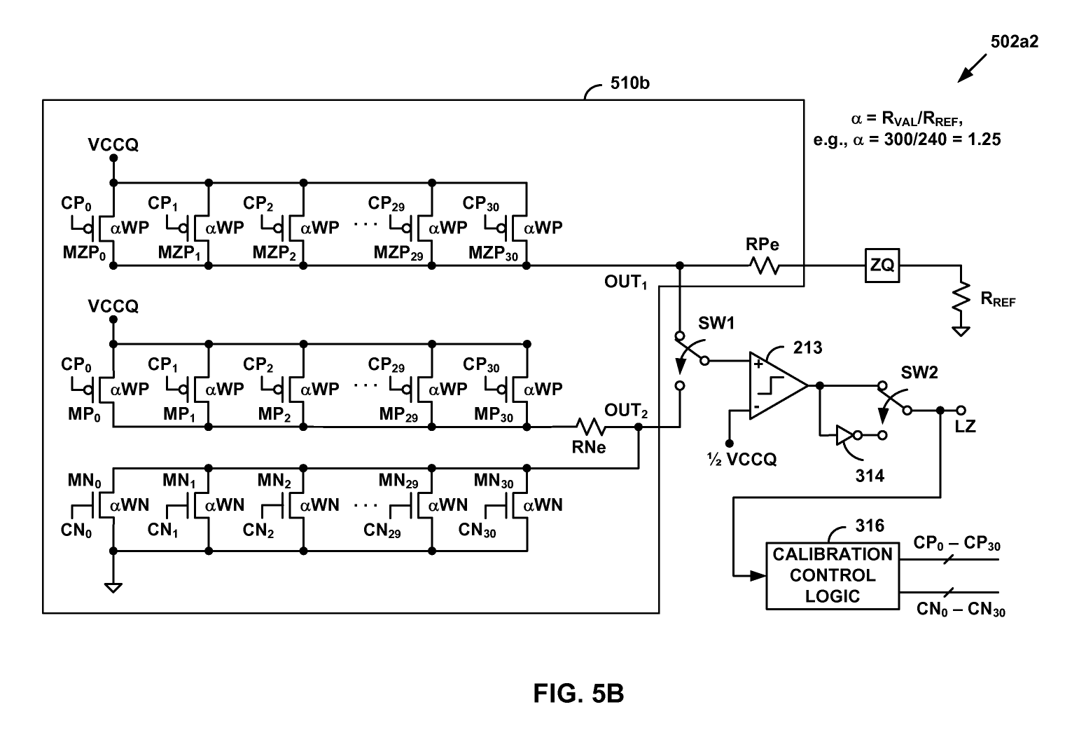

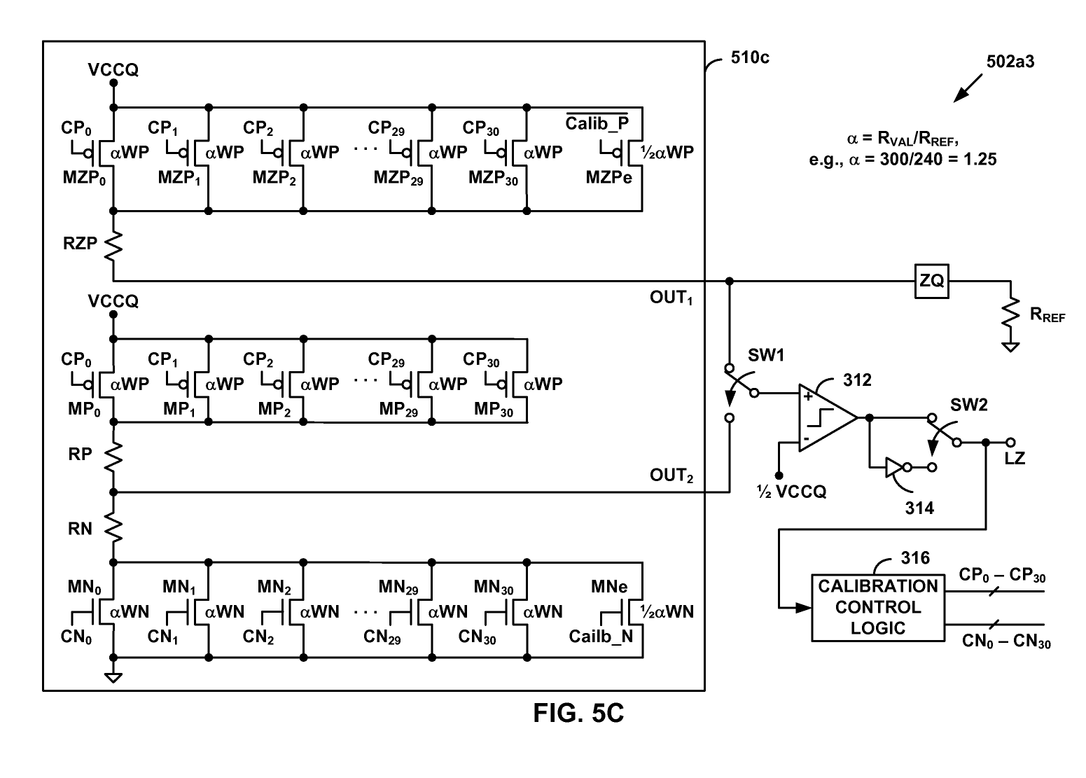

FIG. 5A is a block diagram of an embodiment of an impedance calibration circuit 502a1 of this technology for use with OCD circuit 300a of FIG. 4A. Impedance calibration circuit 502a1 includes a first circuit 510a (also referred to herein as OCD replica circuit 510a), first switch SW1, comparator 312, inverter 314, second switch SW2, calibration control logic 316 and reference resistor R_{REF}. OCD replica circuit 510a has a first output terminal OUT₁ coupled to a first terminal of first switch SW1 and an impedance adjustment terminal ZQ, and a second output terminal OUT₂ coupled to a second terminal of first switch SW1. Reference resistor R_{REF} has a first terminal coupled to impedance adjustment terminal ZQ, and a second terminal coupled to GROUND. In an embodiment, reference resistor R_{REF} is 240 ohms, although other values may be used.

OCD replica circuit 510a includes first PMOS transistors MZP₀, MZP₁, . . . , MZP₃₀, second PMOS transistors MP₀, MP₁, . . . , MP₃₀, and first NMOS transistors MN₀, MN₁, . . . , MN₃₀. In addition, OCD replica circuit 510a includes a third PMOS transistor MZPe and a second NMOS transistor MNe. Third PMOS transistor MZPe is coupled in parallel with first PMOS transistors MZP₀, MZP₁, . . . , MZP₃₀, between a power supply VCCQ and first output terminal OUT₁. Second NMOS transistor MNe is coupled in parallel with first NMOS transistors MN₀, MN₁, . . . , MN₃₀ between second output terminal OUT₂ and GROUND.

First output terminal OUT₁ provides a first output signal of third PMOS transistor MZPe and first PMOS transistors MZP₀, MZP₁, . . . , MZP₃₀, and second output terminal OUT₂ provides a second output signal of second PMOS transistors MP₀, MP₁, . . . , MP₃₀ and second NMOS transistor MNe and first NMOS transistors MN₀, MN₁, . . . , MN₃₀.

Each of first PMOS transistors MZP₀, MZP₁, . . . , MZP₃₀ and second PMOS transistors MP₀, MP₁, . . . , MP₃₀ has a first width αWP and has a gate terminal coupled to a corresponding one of first control signals CP₀, CP₁, . . . , CP₃₀, and each of first NMOS transistors MN₀, MN₁, . . . , MN₃₀ has a second width αWN and has a gate terminal coupled to a corresponding one of second control signals CN₀, CN₁, . . . , CN₃₀. Third PMOS transistor MZPe has a third width one-half the first width of first PMOS transistors MZP₀, MZP₁, . . . , MZP₃₀ (i.e., ½ αWP) and has a gate terminal coupled to a third control signal C̅a̅l̅i̅b̅_̅P̅. Second NMOS transistor MNe has a fourth width one-half the second width of first NMOS transistors MN₀, MN₁, . . . , MN₃₀ (i.e., ½ αWN) and has a gate terminal coupled to a fourth control signal Calib_N. As described above, α=R_{VAL}/R_{REF}, and where R_{VAL} is a nominal targeting impedance of OCD circuit 300a of FIG. 4A. For example, if R_{VAL}=300 ohms and reference resistor R_{REF}=240 ohms, α=1.25.

Calibration control logic 316 varies first control signals CP₀, CP₁, . . . , CP₃₀, second control signals CN₀, CN₁, . . . , CN₃₀, third control signal C̅a̅l̅i̅b̅_̅P̅, and fourth control signal Calib_N, controls first switch SW1 and second switch SW2, and receives as input the signal LZ. During a ZQ calibration process, impedance calibration circuit 502a1 implements the two-step calibration process described above with respect to impedance calibration circuit 302a of FIG. 4C, with third control signal C̅a̅l̅i̅b̅_̅P̅ and fourth control signal Calib_N both pulled LOW during the first calibration step, and with third control signal C̅a̅l̅i̅b̅_̅P̅ and fourth control signal Calib_N both pulled HIGH during the second calibration step. In contrast to the calibration process of FIG. 4C, the calibration error due to step size of impedance calibration circuit 502a1 is one half the calibration error due to step size of impedance calibration circuit 302a of FIG. 4C.

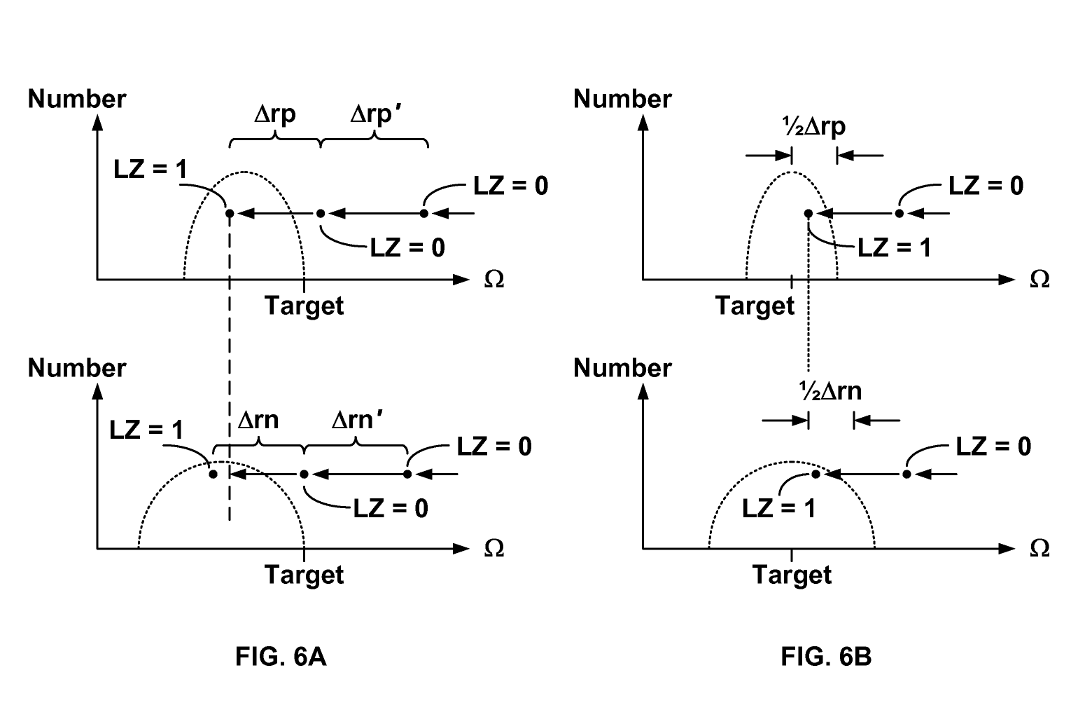

In particular, FIG. 6A depicts a diagram of an example calibration process of previously known impedance calibration circuit 302a of FIG. 4C, and FIG. 6B depicts a diagram of an example calibration process of impedance calibration circuit 502a1 of FIG. 5A. The x-axis in each diagram is impedance, and the y-axis is number. The calibrated impedance forms a distribution because the impedance varies based on process, power supply voltage and temperature. The diagrams in the upper chart in each figure depict example impedance distributions after the first calibration step, and the diagrams in lower chart in each figure depict example impedance distributions after the second calibration step.

In particular, the upper chart in FIG. 6A depicts an example impedance distribution after the first calibration step (pull-up calibration) for previously known impedance calibration circuit 302a of FIG. 4C. In this example, the impedance decreases by Stepsize_P, where Stepsize_P is the last incremental impedance before the calibration passes, resulting from turning ON an additional transistor of first PMOS transistors MZP₀, MZP₁, . . . , MZP₃₀. For example, Stepsize_P may have a value of about 10 ohms. The value of Stepsize_P equals the impedance of reference resistor R_{REF} divided by the number of first PMOS transistors MZP₀, MZP₁, . . . , MZP₃₀ that are turned ON.

Referring again to FIG. 4C, if the impedance of first PMOS transistors MZP₀, MZP₁, . . . , MZP₃₀ is greater than the impedance of reference resistor R_{REF}, the output of comparator 312 is LZ=0, and if the impedance of first PMOS transistors MZP₀, MZP₁, . . . , MZP₃₀ is less than the impedance of reference resistor R_{REF}, the output of comparator 312 is LZ=1. If LZ turns from 0 to 1, the impedance of first PMOS transistors MZP₀, MZP₁, . . . , MZP₃₀ with LZ=1 is referred to herein as the “calibrated pull-up impedance” or “P_{CAL}.” As depicted in the upper chart of FIG. 6A, P_{CAL} distributes from (Target impedance) to (Target impedance−Stepsize_P). In an example embodiment, Target impedance is 240 ohms, although other values may be used.

The pull-up impedance deviation may be defined as the difference between P_{CAL} and the Target impedance:

Impedance deviation_{P}=P_{CAL}−Target impedance

So a minimum and a maximum pull-up impedance deviation are −Stepsize_P and 0, respectively.

The lower chart in FIG. 6A depicts an example impedance distribution after the second calibration step (pull-down calibration) for previously known impedance calibration circuit 302a of FIG. 4C. In this example, the impedance decreases by Stepsize_N, where Stepsize_N is the last incremental impedance before the calibration passes, resulting from turning ON an additional transistor of first NMOS transistors MN₀, MN₁, . . . , MN₃₀. For example, Stepsize_N may have a value of about 10 ohms. The value of Stepsize_N equals the impedance of reference resistor R_{REF} divided by the number of first NMOS transistors MN₀, MN₁, . . . , MN₃₀ that are turned ON.

Referring again to FIG. 4C, if the impedance of first NMOS transistors MN₀, MN₁, . . . , MN₃₀ is greater than the impedance of calibrated second PMOS transistors MP₀, MP₁, . . . , MP₃₀, the output of inverter 314 is LZ=0, and if the impedance of first NMOS transistors MN₀, MN₁, . . . , MN₃₀ is less than the impedance of calibrated second PMOS transistors MP₀, MP₁, . . . , MP₃₀, the output of inverter 314 is LZ=1. If LZ turns from 0 to 1, the impedance of first NMOS transistors MN₀, MN₁, . . . , MN₃₀ with LZ=1 is referred to herein the “calibrated pull-down impedance” or “N_{CAL}.” As depicted in the lower chart of FIG. 6A, N_{CAL} distributes from (Target impedance−Stepsize_P−Stepsize_N) to (Target impedance).

The pull-down impedance deviation may be defined as the difference between N_{CAL} and the Target impedance:

Impedance deviation_{N}=N_{CAL}−Target impedance

So a minimum and a maximum pull-down impedance deviation are (−Stepsize_P−Stepsize_N) and 0, respectively.

The pull-up/pull-down imbalance may be defined as:

$$\frac{P}{N} imbalance = \frac{( {P}_{CAL} - {N}_{CAL} )}{Target Impedance}$$

Then for previously known impedance calibration circuit 302a of FIG. 4C, the maximum pull-up/pull-down imbalance is:

$$\vert \frac{P}{N} imbalance \vert = \frac{Stepsize\_N}{Target impedance}$$

In contrast, the upper chart in FIG. 6B depicts an example impedance distribution after the first calibration step (pull-up calibration) for impedance calibration circuit 502a1 of FIG. 5A. In this example, the impedance decreases Stepsize_P by Stepsize_P, where Stepsize_P is the ON-resistance of each transistor of first PMOS transistors MZP₀, MZP₁, . . . , MZP₃₀.

Referring again to FIG. 5A, if the impedance of first PMOS transistors MZP₀, MZP₁, . . . , MZP₃₀ is greater than the impedance (R_{REF}−0.5*Stepsize_P), the output of comparator 312 is LZ=0, and if the impedance of first PMOS transistors MZP₀, MZP₁, . . . , MZP₃₀ is less than the impedance (R_{REF}−0.5*Stepsize_P), the output of comparator 312 is LZ=1. This is because the impedance of first PMOS transistors MZP₀, MZP₁, . . . , MZP₃₀ and third PMOS transistor MZPe is lower than the impedance of just first PMOS transistors MZP₀, MZP₁, . . . , MZP₃₀ because third PMOS transistor MZPe has extra resistance of 0.5*Stepsize_P. As depicted in the upper chart of FIG. 6B, P_{CAL} distributes from (Target impedance+0.5*Stepsize_P) to (Target impedance−0.5*Stepsize_P). A minimum and maximum pull-up impedance deviation are (−0.5*Stepsize_P) and (0.5*Stepsize_P), respectively. Thus, the maximum magnitude of pull-up impedance deviation is one-half that of previously known impedance calibration circuit 302a of FIG. 4C. Persons of ordinary skill in the art will understand that to find boundary of LZ=0 and LZ=1, a binary search algorithm can be used instead of decreasing or increasing impedance step by step.

The lower chart in FIG. 6B depicts an example impedance distribution after the second calibration step (pull-down calibration) for impedance calibration circuit 502a1 of FIG. 5A. In this example, the impedance decreases Stepsize_N by Stepsize_N. If the impedance of first NMOS transistors MN₀, MN₁, . . . , MN₃₀ is greater than (the impedance of calibrated second PMOS transistors MP₀, MP₁, . . . , MP₃₀−0.5*Stepsize_N₁, the output of inverter 314 is LZ=0, and if the impedance of first NMOS transistors MN₀, MN₁, . . . , MN₃₀ is less than (the impedance of calibrated second PMOS transistors MP₀, MP₁, . . . , MP₃₀−0.5*Stepsize_N), the output of inverter 314 is LZ=1. This is because the impedance of first NMOS transistors MN₀, MN₁, . . . , MN₃₀ and second NMOS transistor MNe is lower than the impedance of just first NMOS transistors MN₀, MN₁, . . . , MN₃₀ because second NMOS transistor MNe has extra resistance of 0.5*Stepsize_N. Persons of ordinary skill in the art will understand that to find boundary of LZ=0 and LZ=1, a binary search algorithm can be used instead of decreasing or increasing impedance step by step.

As depicted in the lower chart of FIG. 6B, N_{CAL} distributes from (0.5*Stepsize_N+0.5*Stepsize_P) to (−0.5*Stepsize_N−0.5*Stepsize_P). So maximum calibration error is 0.5*Stepsize_N+0.5*Stepsize_P, respectively. The maximum magnitude of P/N imbalance=0.5*Stepsize_N/(Target impedance), which is half that of previously known impedance calibration circuit 302a of FIG. 4C.

Without wanting to be bound by any particular theory, it is believed that third PMOS transistor MPe and second NMOS transistor MNe work to reduce both the magnitudes of the pull-up and pull-down impedance deviation and the magnitude of the P/N imbalance.

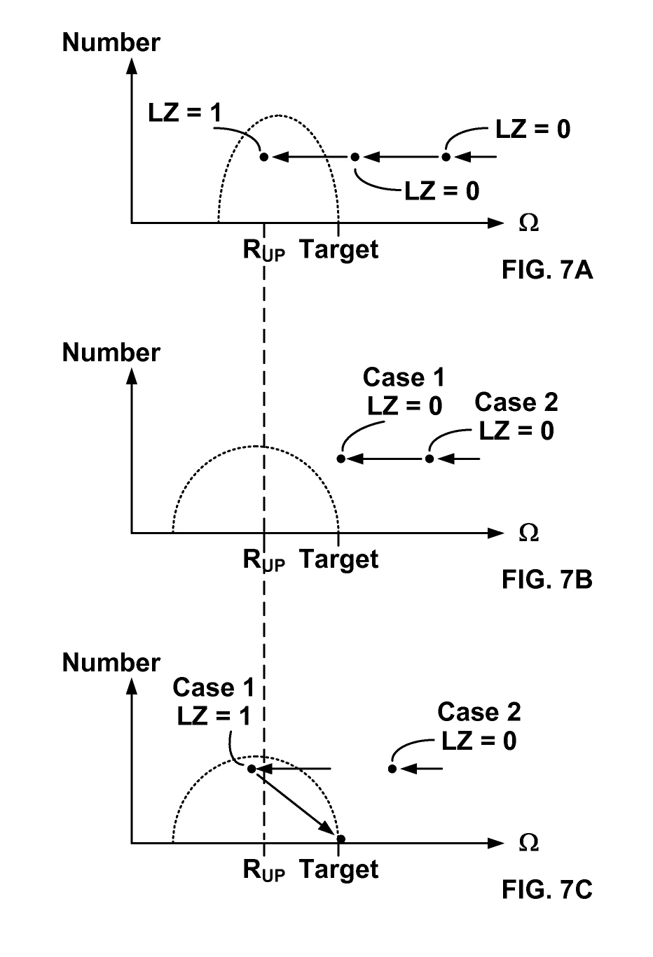

FIG. 7A depicts a diagram of another example pull-up calibration of impedance calibration circuit 502a1 of FIG. 5A, FIG. 7B depicts a diagram of another example pull-down calibration of previously known impedance calibration circuit 302a of FIG. 4C, and FIG. 7C depicts a diagram of another example pull-down calibration process of impedance calibration circuit 502a1 of FIG. 5A. In FIG. 7A, assume that second PMOS transistors MP₀, MP₁, . . . , MP₃₀ are calibrated to an impedance R_UP with a decrementing direction with respect to a target impedance as shown. In FIG. 7B, assume that first NMOS transistors MN₀, MN₁, . . . , MN₃₀ are then calibrated in a decrementing direction with respect to R_UP, so the impedance is the lowest at the last step. In Case 1, the pull-down impedance happens to be on the higher side of R_UP and close enough (<Stepsize_N) to R_UP. The output of comparator 312 is LZ=0. On the other hand, in Case 2, the pull-down impedance happens to be on the higher side of R_UP but far (>Stepsize_N) from R_UP. The output of comparator 312 is LZ=0, also. Because we cannot distinguish Case 1 from Case 2 and we need to regard Case 2 as a “fail” case, we need to regard Case 1 as a “fail” case even though the error is small enough. So impedance calibration margin such as minimum power source voltage or maximum temperature will become smaller by regarding Case 1 as a “fail” case.

In contrast, FIG. 7C shows first NMOS transistors MN₀, MN₁, . . . , MN₃₀ are calibrated in a decrementing direction with respect to R_UP, so the last step is the lowest impedance. This configuration includes second NMOS transistor MNe that has a conductance of Stepsize_N. Case 1 corresponds to the same process, voltage and temperature variation as in FIG. 7B. Because impedance calibration circuit 502a1 of FIG. 5A includes second NMOS transistor MNe, the impedance is lower than that of FIG. 7B by Stepsize_N, and the pull-down impedance is on the lower side of R_UP. The output of comparator 312 is LZ=1. On the other hand, in Case 2, the pull-down impedance is on the higher side of R_UP. The output of comparator 312 is LZ=0. Therefore, for Case 1, less than Stepsize_N from R_UP, is a “pass” case. For Case 2, more than Stepsize_N from R_UP, is a “fail” case. Now we can distinguish Case 1 from Case 2, and Case 1 does not need to be regarded as a “fail” case.

Without wanting to be bound by any particular theory, it is believed that impedance calibration circuit 502a1 can be used to avoid losing impedance calibration margin such as minimum power source voltage or maximum temperature.

Referring again to FIG. 5A, persons of ordinary skill in the art will understand that the width of third PMOS transistor MPe and second NMOS transistor MNe does not need to be ½ αWP and ½ αWN, respectively. For example, the width of third PMOS transistor MPe and second NMOS transistor MNe can be αWP and αWN, respectively. In such an embodiment, referring again to FIG. 7C, an upper impedance limit of Case 1 is larger. So calibration has a greater chance to be a “pass,” but error such as magnitude of impedance deviation and magnitude of P/N imbalance will be larger.

FIG. 5B is a block diagram of an embodiment of another impedance calibration circuit 502a2 of this technology for use with OCD circuit 300a of FIG. 4A. Instead of using extra transistors as in impedance calibration circuit 502a1, impedance calibration circuit 502a2 includes extra resistors. In particular, impedance calibration circuit 502a2 includes a first circuit 510b (also referred to herein as OCD replica circuit 510b), first switch SW1, comparator 312, inverter 314, second switch SW2, calibration control logic 316 and reference resistor R_{REF}. OCD replica circuit 510b has a first output terminal OUT₁ coupled to a first terminal of first switch SW1 and a first terminal of a first resistor RPe, and a second output terminal OUT₂ coupled to a second terminal of first switch SW1. First resistor RPe has a second terminal coupled to impedance adjustment terminal ZQ. Reference resistor R_{REF} has a first terminal coupled to impedance adjustment terminal ZQ, and a second terminal coupled to GROUND. In an embodiment, reference resistor R_{REF} is 240 ohms, although other values may be used.

OCD replica circuit 510b includes first PMOS transistors MZP₀, MZP₁, . . . , MZP₃₀, second PMOS transistors MP₀, MP₁, . . . , MP₃₀, and first NMOS transistors MN₀, MN₁, . . . , MN₃₀. In addition, OCD replica circuit 510b includes a second resistor RNe coupled between first PMOS transistors MZP₀, MZP₁, . . . , MZP₃₀ first output terminal OUT₁.

First resistor RPe has a resistance equal to ½ Stepsize_P and second resistor MNe has a resistance equal to ½ Stepsize_N. For example, if Stepsize_P=10 ohms and Stepsize_N=10 ohms, first resistor RPe has a resistance of 5 ohms, and second resistor RNe has a resistance of 5 ohms. Other resistance values may be used. First resistor RPe and second resistor RNe each can be formed using metal, polysilicon or other materials. Persons of ordinary skill in the art will understand that because resistor impedance varies independently from transistor impedance, unlike third PMOS transistor MZPe and second NMOS transistor MNe of FIG. 5A, the effect will also vary independently from transistors. As a result, the calibration error of OCD replica circuit 510b of FIG. 5B may be larger than that of OCD replica circuit 510a of FIG. 5A.

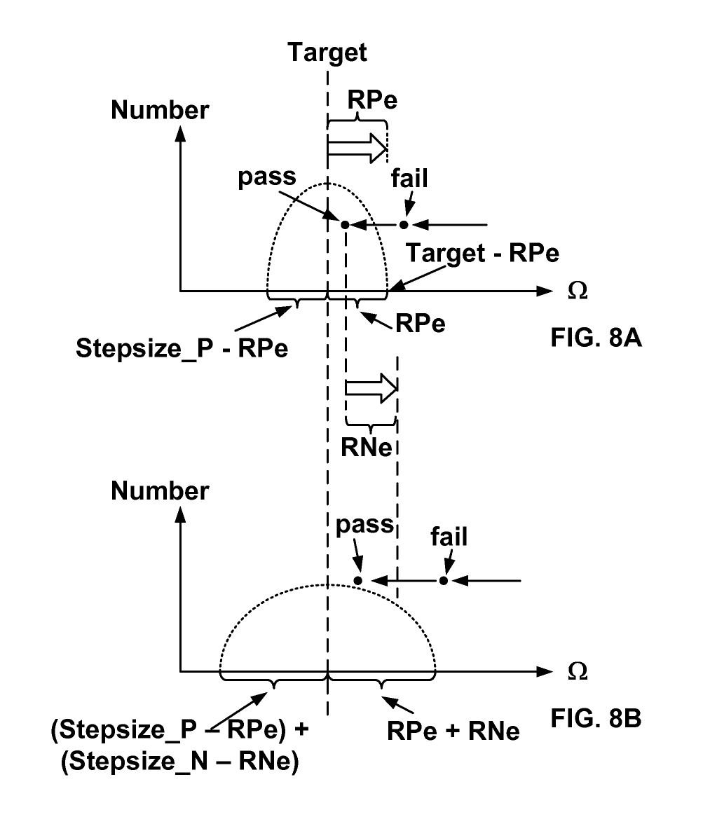

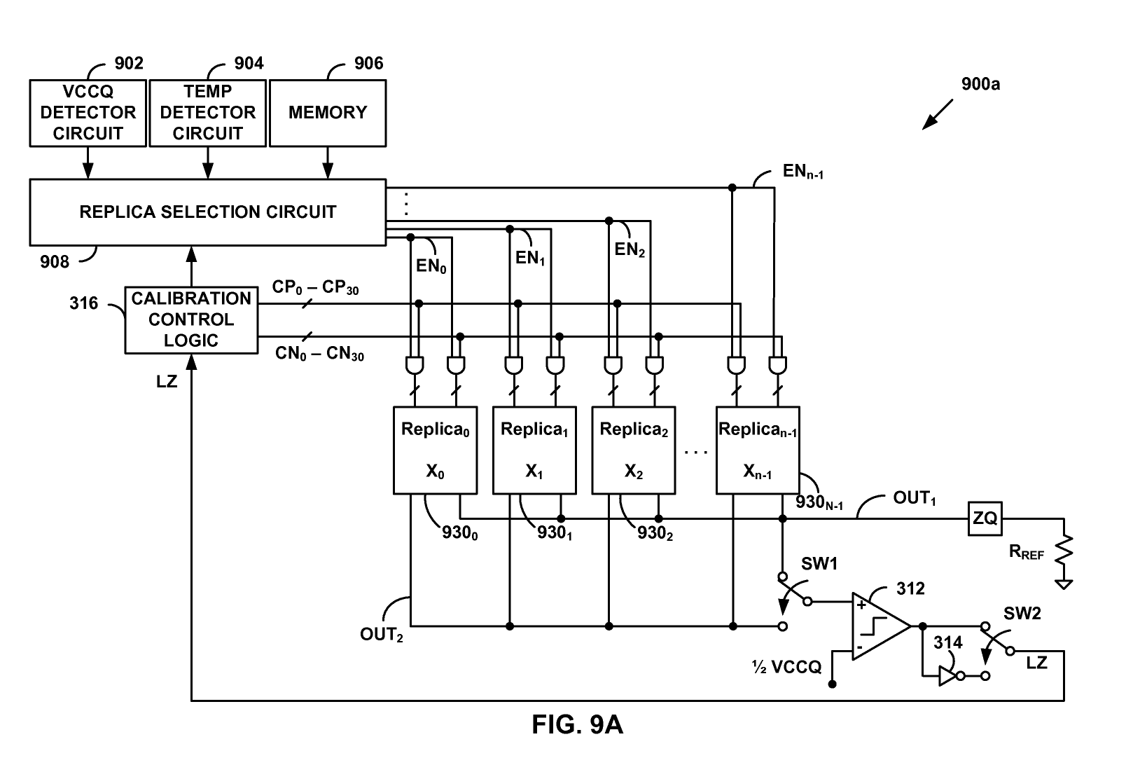

FIG. 8A illustrates an example pull-up impedance calibration for OCD replica circuit 510b of FIG. 5B, and FIG. 8B illustrates an example pull-down impedance calibration for OCD replica circuit 510b of FIG. 5B The maximum magnitude of P/N imbalance is the greater of

[(Stepsize_N−RNe)/(Target impedance)] and [RNe/(Target impedance)].

Thus, the pull-down impedance deviation is better than that of previously known impedance calibration circuit 302a of FIG. 4C. But the pull up impedance deviation and maximum magnitude of P/N imbalance are greater than that of impedance calibration circuit 502a1 of FIG. 5A.

FIG. 5C is a block diagram of an embodiment of still another impedance calibration circuit 502a3 of this technology for use with OCD circuit 300a of FIG. 4A. In this embodiment, impedance calibration circuit 502a3 includes third PMOS transistor MZPe and second NMOS transistor MNe, a first pull-up resistor RZP, a second pull-up resistor RP and a pull-down resistor RN.

In particular, impedance calibration circuit 502a3 includes a first circuit 510c (also referred to herein as OCD replica circuit 510c), first switch SW1, comparator 312, inverter 314, second switch SW2, calibration control logic 316 and reference resistor R_{REF}. OCD replica circuit 510c has a first output terminal OUT₁ coupled to a first terminal of first switch SW1 and impedance adjustment terminal ZQ, and a second output terminal OUT₂ coupled to a second terminal of first switch SW1. Reference resistor R_{REF} has a first terminal coupled to impedance adjustment terminal ZQ, and a second terminal coupled to GROUND. In an embodiment, reference resistor R_{REF} is 240 ohms, although other values may be used.

OCD replica circuit 510c includes first PMOS transistors MZP₀, MZP₁, . . . , MZP₃₀, second PMOS transistors MP₀, MP₁, . . . , MP₃₀, and first NMOS transistors MN₀, MN₁, . . . , MN₃₀. In addition, OCD replica circuit 510a includes third PMOS transistor MZPe, second NMOS transistor MNe, first pull-up resistor RZP, second pull-up resistor RP and pull-down resistor RN.

First PMOS transistors MZP₀, MZP₁, . . . , MZP₃₀ are coupled in parallel between power supply VCCQ and a first terminal of first pull-up resistor RZP, which has a second terminal coupled to first output terminal OUT₁. Third PMOS transistor MZPe is coupled in parallel with first PMOS transistors MZP₀, MZP₁, . . . , MZP₃₀, between power supply VCCQ and the first terminal of first pull-up resistor RZP. First pull-up resistor RZP may have a value about 50% of R_{REF}. For example, in an embodiment, R_{REF}=240 ohms, and RZP=120 ohms. Other values may be used. However, larger values of RZP (e.g., 70% of R_{REF}) require larger layout area and transistor sizes for first PMOS transistors MZP₀, MZP₁, . . . , MZP₃₀. Smaller values of RZP (e.g., 30% of R_{REF}) may result in larger shoot-through current due to stronger non-linearity. Thus, a value of RZP of about 50% of R_{REF} is a good compromise between these two alternatives.

Second PMOS transistors MP₀, MP₁, . . . , MP₃₀ are coupled in parallel between power supply VCCQ and a first terminal of second pull-up resistor RP, which has a second terminal coupled to second output terminal OUT₂. Second pull-up resistor RP may have a value of about 50% of R_{REF}. For example, in an embodiment, R_{REF}=240 ohms, and RP=120 ohms. Other values may be used. However, larger values of RP (e.g., 70% of R_{REF}) require larger layout area and transistor sizes for second PMOS transistors MP₀, MP₁, . . . , MP₃₀. Smaller values of RP (e.g., 30% of R_{REF}) may result in larger shoot-through current due to stronger non-linearity. Thus, a value of RP of about 50% of R_{REF} is a good compromise between these two alternatives.

First NMOS transistors MN₀, MN₁, . . . , MN₃₀ are coupled in parallel between GROUND and a first terminal of pull-down resistor RN, which has a second terminal coupled to second output terminal OUT₂. Second NMOS transistor MNe is coupled in parallel with first NMOS transistors MN₀, MN₁, . . . , MN₃₀ between GROUND and the first terminal of pull-down resistor RN. Pull-down resistor RN may have a value of about 50% of R_{REF}. For example, in an embodiment, R_{REF}=240 ohms, and RN=120 ohms. Other values may be used. However, larger values of RN (e.g., 70% of R_{REF}) require larger layout area and transistor sizes for first NMOS transistors MN₀, MN₁, . . . , MN₃₀. Smaller values of RN (e.g., 30% of R_{REF}) may result in larger shoot-through current due to stronger non-linearity. Thus, a value of RN of about 50% of R_{REF} is a good compromise between these two alternatives.

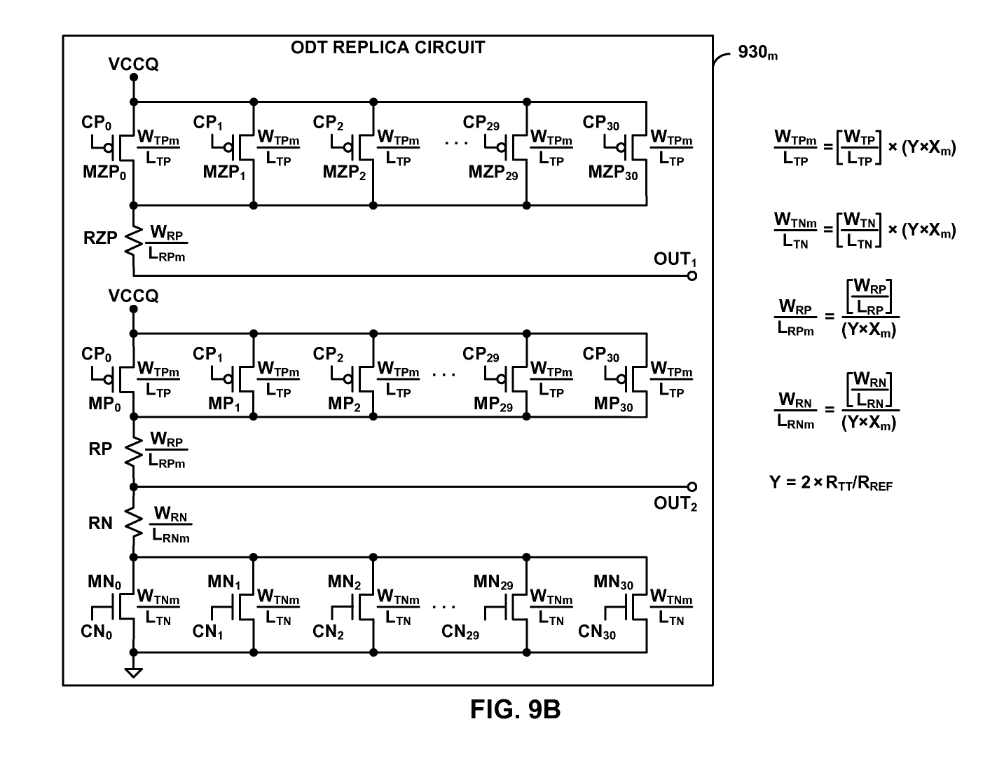

FIG. 9A is a block diagram of an embodiment of another impedance calibration circuit 900a of this technology for use with ODT circuit 300b of FIG. 4B. Impedance calibration circuit 900a includes power supply detector circuit 902, temperature detector circuit 904, memory 906 (e.g., ROM), replica selection circuit 908, first switch SW1, comparator 312, inverter 314, second switch SW2, calibration control logic 316, reference resistor R_{REF} and N first circuits 930₀, 930₁, . . . , 930_{N-1} (also referred to herein as ODT replica circuits 930₀, 930₁, . . . , 930_{N-1}). As described in more detail below, each of ODT replica circuits 930₀, 930₁, . . . , 930_{N-1} is configured to target a corresponding unique target impedance. Each of ODT replica circuits 930₀, 930₁, . . . , 930_{N-1} has a corresponding associated scalar coefficient X₀, X₁, . . . , X_{N-1}, respectively.

In particular, impedance calibration circuit 900a can target plural resistances instead of targeting a fixed resistance. When the non-linearity of the pull-up and pull-down transistor is larger (as a result of variations in process, voltage and temperature), the impedance error will be smaller if a lower target resistance is used. To use a lower target resistance, impedance calibration circuit 900a uses N ODT replica circuits 930₀, 930₁, . . . , 930_{N-1}. When an impedance calibration is executed, replica selection circuit 908, which is controlled by calibration control logic 316, selects one of N ODT replica circuits 930₀, 930₁, . . . , 930_{N-1} based on process, voltage and temperature information provided by power supply detector circuit 902, temperature detector circuit 904, memory 906.

Each of ODT replica circuits 930₀, 930₁, . . . , 930_{N-1} has a first output terminal OUT₁ coupled to a first terminal of first switch SW1 and an impedance adjustment terminal ZQ, and a second output terminal OUT₂ coupled to a second terminal of first switch SW1. Reference resistor R_{REF} has a first terminal coupled to impedance adjustment terminal ZQ, and a second terminal coupled to GROUND. In an embodiment, reference resistor R_{REF} is 240 ohms, although other values may be used.

FIG. 9B is a block diagram of an example embodiment of one of ODT replica circuits 930₀, 930₁, . . . , 930_{N-1}. In particular, ODT replica circuit 930ₘ includes first PMOS transistors MZP₀, MZP₁, . . . , MZP₃₀, second PMOS transistors MP₀, MP₁, . . . , MP₃₀, first NMOS transistors MN₀, MN₁, . . . , MN₃₀, first pull-up resistor RZP, second pull-up resistor RP and pull-down resistor RN.

First PMOS transistors MZP₀, MZP₁, . . . , MZP₃₀ are coupled in parallel between power supply VCCQ and a first terminal of first pull-up resistor RZP, which has a second terminal coupled to first output terminal OUT₁. Each of first PMOS transistors MZP₀, MZP₁, . . . , MZP₃₀ has a width/length of W_{TPm}/L_{TP}. First pull-up resistor RZP has a width/length of W_{RP}/L_{RPm}.

Second PMOS transistors MP₀, MP₁, . . . , MP₃₀ are coupled in parallel between power supply VCCQ and a first terminal of second pull-up resistor RP, which has a second terminal coupled to second output terminal OUT₂. Each of second PMOS transistors MP₀, MP₁, . . . , MP₃₀ has a width/length of W_{TPm}/L_{TP}. Second pull-up resistor RP has a width/length of W_{RP}/L_{RPm}.

First NMOS transistors MN₀, MN₁, . . . , MN₃₀ are coupled in parallel between GROUND and a first terminal of pull-down resistor RN, which has a second terminal coupled to second output terminal OUT₂. Each of first NMOS transistors MN₀, MN₁, . . . , MN₃₀ has a width/length of W_{TNm}/L_{TN}. Pull-down resistor RN has a width/length of W_{RN}/L_{RNm}.

With respect to resistor width/length values W_{RP}/L_{RPm} and W_{RN}/L_{RNm}, the wider the width, the lower the impedance of the resistor, and the shorter the length, the lower the impedance of the resistor. With respect to linearity, the greater the ratio W_{TPm}/L_{TP}, the more linear is the on-resistance of the transistor, and the lower the ratio W_{TNm}/L_{TN}, the more linear is the resistance of the resistor. However, generally transistor and resistor size increases for better linearity.

The width/length values for first PMOS transistors MZP₀, MZP₁, . . . , MZP₃₀, second PMOS transistors MP₀, MP₁, . . . , MP₃₀, first NMOS transistors MN₀, MN₁, . . . , MN₃₀, first pull-up resistor RZP, second pull-up resistor RP and pull-down resistor RN are:

$$\frac{{W}_{TPm}}{{L}_{TP}} = ( \frac{{W}_{TP}}{{L}_{TP}} ) \times ( Y \times {X}_{m} )$$

$$\frac{{W}_{TNm}}{{L}_{TN}} = ( \frac{{W}_{TN}}{{L}_{TN}} ) \times ( Y \times {X}_{m} )$$

$$\frac{{W}_{RP}}{{L}_{RPm}} = \frac{( \frac{{W}_{RP}}{{L}_{RP}} )}{( Y \times {X}_{m} )}$$

$$\frac{{W}_{RN}}{{L}_{RNm}} = \frac{( \frac{{W}_{RN}}{{L}_{RN}} )}{( Y \times {X}_{m} )}$$

where W_{TP}/L_{TP}, W_{TN}/L_{TN}, W_{RP}/L_{RP} and W_{RN}/L_{RN} are nominal width/length values for first PMOS transistors MZP₀, MZP₁, . . . , MZP₃₀, second PMOS transistors MP₀, MP₁, . . . , MP₃₀, first NMOS transistors MN₀, MN₁, . . . , MN₃₀, first pull-up resistor RZP, second pull-up resistor RP and pull-down resistor RN, respectively, Xₘ is the scalar coefficient associated with ODT replica circuit 930ₘ, and Y=(2×R_{TT})/R_{REF}, where (2×R_{TT}) is a nominal target resistance. In an example embodiment, (2×R_{TT})=300 ohms and R_{REF}=240 ohms, although other values may be used.

In an example embodiment, X₀=1, X₁=0.95, X₂=0.90, . . . , although other scalar coefficient values may be used, and may be empirically determined. In such an embodiment, ODT replica circuit 930₀ (with X₀=1) may be used for targeting the nominal impedance (2×R_{TT}), ODT replica circuit 930₁ (with X₁=0.95) may be used for targeting an impedance 0.95×(2×R_{TT}), ODT replica circuit 930₂ (with X₂=0.90) may be used for targeting an impedance 0.90×(2×R_{TT}), and so on. ODT replica circuit 930₁ may be used instead of ODT replica circuit 930₀ when in the ODT structure resistance varies low and transistor impedance varies high (i.e., the impedance linearity is worse). The same principle applies for both the replica ODT pull-down structure and the replica ODT pull-up structure.

Referring again to FIG. 9A, VCCQ detector circuit 902 provides a signal to replica selection circuit 908 indicating the value of power supply voltage VCCQ. Likewise, temperature detector circuit 904 provides a signal to replica selection circuit 908 indicating chip temperature data. Memory 908 provides replica selection circuit 908 with data regarding process variation information, such as transistor Ids and resistance variation. Based on this information, replica selection circuit 908 determines which of ODT replica circuits 930₀, 930₁, . . . , 930_{N-1} should be used during calibration, and activates a corresponding one of enable signals EN₀, EN₁, . . . , EN_{N-1}.

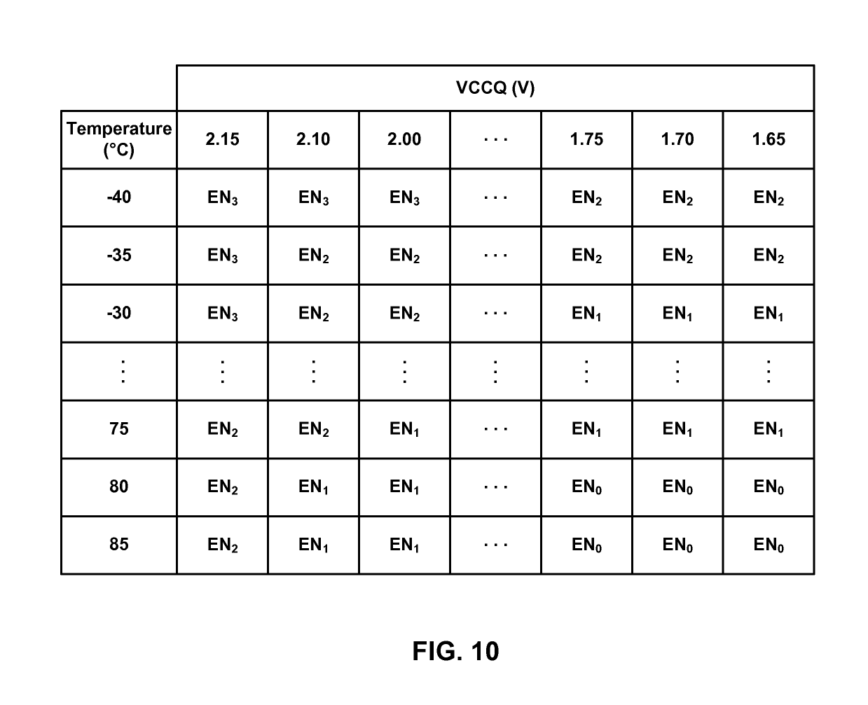

In an embodiment, replica selection circuit 908 can use a look up table (LUT), such as depicted in FIG. 10, to determine which of ODT replica circuits 930₀, 930₁, . . . , 930_{N-1} should be used during calibration. In the example LUT depicted in FIG. 10, the LUT outputs which replica to use based on VCCQ and temperature. Other parameters may be used. In an embodiment, a LUT can store any non-linear relations between VCCQ and replica selection and between temperature and replica selection. In another embodiment, replica selection circuit 908 can use a calculator to output which of ODT replica circuits 930₀, 930₁, . . . , 930_{N-1} should be used based on VCCQ, temperature, or other parameters.

After replica selection circuit 908 selects one of ODT replica circuits 930₀, 930₁, . . . , 930_{N-1}, calibration control logic 316 performs a calibration. In an embodiment, calibration control logic 316 may be a state machine that receives signal LZ and performs calibration, such as ZQ calibration described above. Persons of ordinary skill in the art will understand that the multiple target impedance method also may be applied to OCD calibration.

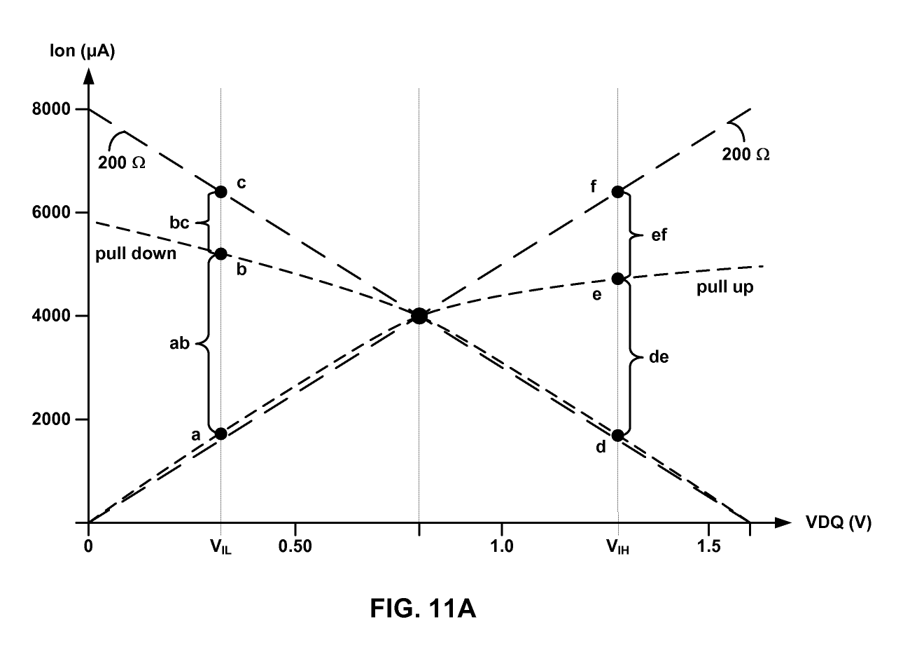

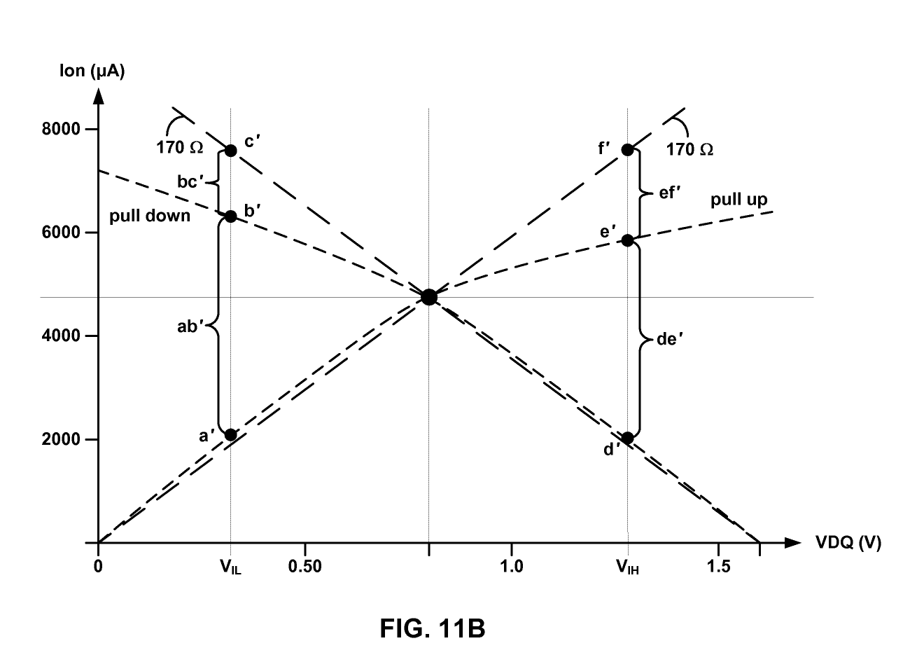

FIGS. 11A-11B illustrate that the impedance error will be smaller if a lower target resistance is used. FIGS. 11A-11B depict currents Ion that flow through the pull-up ODT structure and the pull-down ODT structure of ODT circuit 300b of FIG. 4B for various voltages on DQ pin. FIG. 11A depicts an embodiment is which the impedance calibration function targets 200 ohms for pull-up and pull-down to achieve R_{TT}=100 ohms. R_{TT} is defined as:

$$RTT = \frac{{V}_{IH} - {V}_{IL}}{{I}_{DQ} ( {V}_{IH} ) - {I}_{DQ} ( {V}_{IL} )}$$

where V_{IH}, V_{IL}, I_{DQ}(V_{IH}) and I_{DQ} (V_{IL}) are input high voltage (e.g., 0.8*VCCQ), input low voltage (e.g., 0.2*VCCQ), the current that flows into the DQ pin when the voltage at the DQ pin, VDQ=VIH, and the current that flow into the DQ pin when VDQ=V_{IL}, respectively. At first, the impedance calibration function adjusts pull-up Ion such that Ion(50% of VCCQ) and (50% of VCCQ)/200 ohms match (at the dot in the center of the chart). Then the impedance calibration function adjusts pull-down Ion such that pull-up Ion(50% of VCCQ) and pull-down Ion(50% of VCCQ) match.

Because both the pull-up ODT structure and the pull-down ODT structure turn ON when the ODT circuit is on, I_{DQ}(V_{IH})=pull-up Ion(V_{IH})−pull down Ion(V_{IL}), i.e., the length of the line segment “de.” In addition, I_{DQ}(V_{IL})=pull-up Ion(V_{IL})−pull-down Ion(V_{IL}), i.e., the length of the line segment “ab.” If the ODT structures were composed of only pure resistance of 200 ohms, I_{DQ}(V_{IH}) would be the length of the line segment “df,” and I_{DQ}(V_{IL}) would be the length of the line segment “ac.” R_{TT} would exactly be 100 ohms. So the larger (the length of the line segment “bc”+the length of the line segment “ef”), the greater is the R_{TT} error.

When the impedance calibration function targets 200 ohms for pull-up ODT structure, R_{TT} is 155 ohms for the case of the chart in FIG. 11A. On the other hand, as shown in the chart in FIG. 11B, when the impedance calibration function targets 170 ohms, which is lower than the nominal value for pull-up ODT structure, the curves of Ion are steeper than target=200 ohms case. R_{TT} is then 118 ohms, and is closer to the target of 100 ohms.

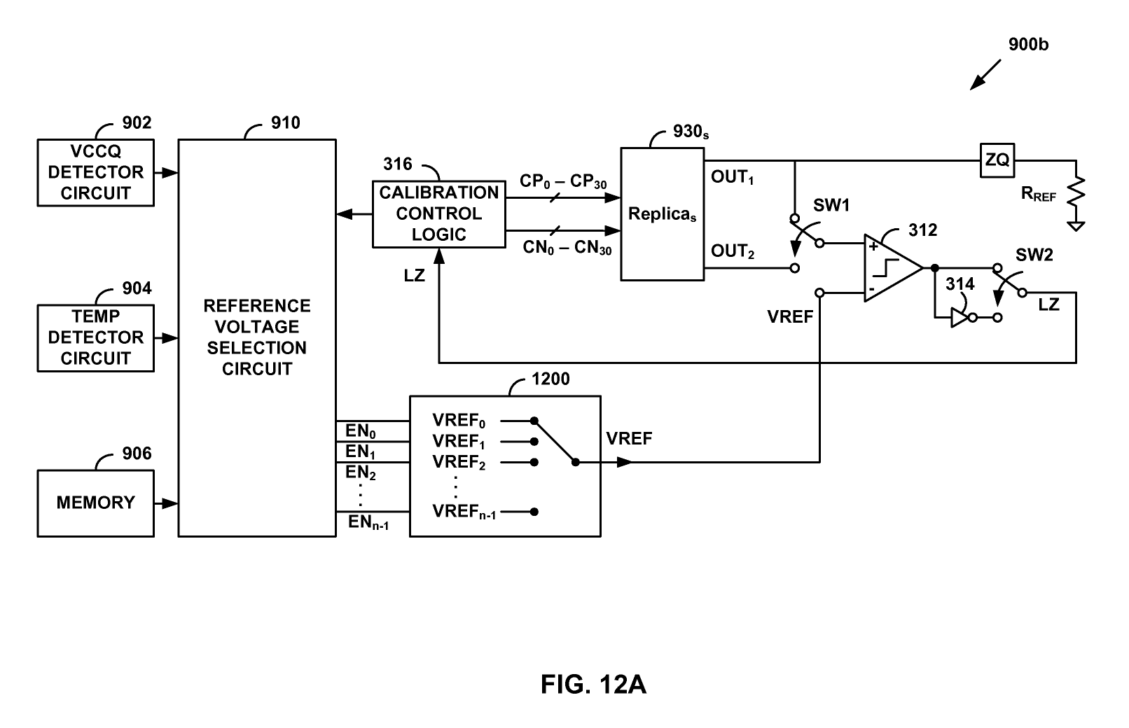

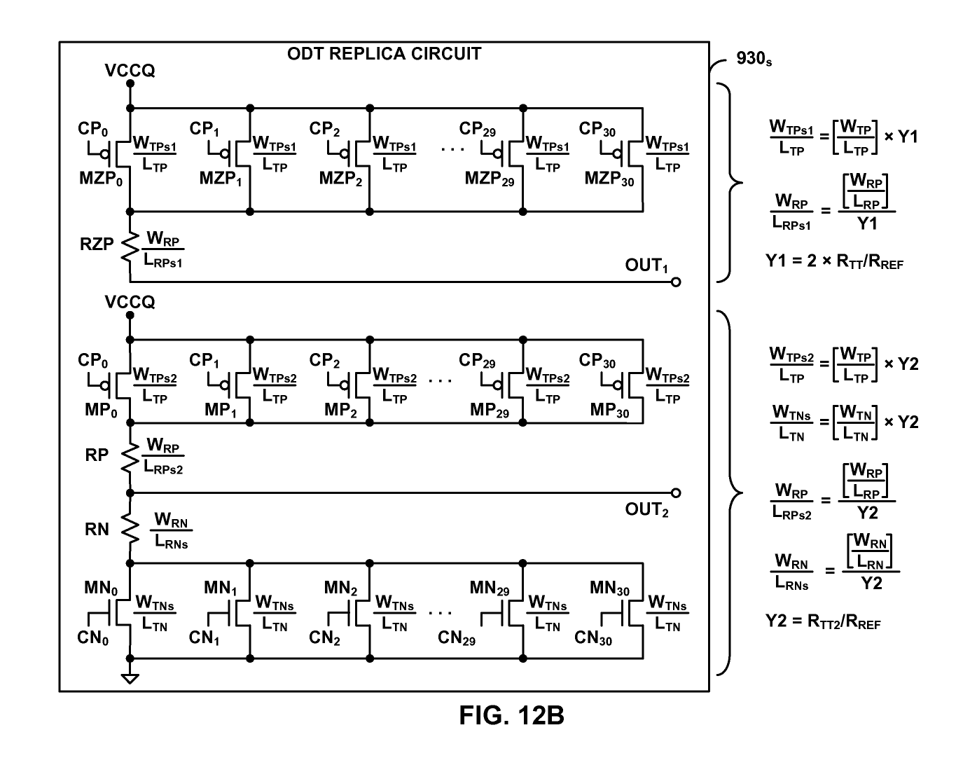

FIG. 12A is a block diagram of another impedance calibration circuit 900b of this technology for use with ODT circuit 300b of FIG. 4B. Impedance calibration circuit 900b includes power supply detector circuit 902, temperature detector circuit 904, memory 906 (e.g., ROM), reference voltage selection circuit 910, first switch SW1, comparator 312, inverter 314, second switch SW2, calibration control logic 316, reference resistor R_{REF} and first circuit 930ₛ (referred to herein as ODT replica circuit 930ₛ).

In contrast to impedance calibration circuit 900a of FIG. 9A, impedance calibration circuit 900b uses a single ODT replica circuit 930ₛ and multiple V_{REF} reference voltages provided by reference voltage generator circuit 1200 instead of using multiple ODT replica circuits 930₀, 930₁, . . . , 930_{N-1}.

For example, to reduce the target impedance, replica selection circuit 908 selects a V_{REF} voltage higher than 0.5*VCCQ during pull-up ODT structure calibration. As a result, the pull-up ODT structure then needs to achieve lower impedance, so that the target impedance is reduced. During pull-down ODT structure calibration, V_{REF} is set to 0.5*VCCQ because the pull-up ODT structure has already been adjusted to a lower impedance, and the pull-down ODT structure impedance is adjusted to match the pull-up structure impedance

An example embodiment of ODT replica circuit 930ₛ is depicted in FIG. 12B. ODT replica circuit 930ₛ includes first PMOS transistors MZP₀, MZP₁, . . . , MZP₃₀, second PMOS transistors MP₀, MP₁, . . . , MP₃₀, first NMOS transistors MN₀, MN₁, . . . , MN₃₀, first pull-up resistor RZP, second pull-up resistor RP and pull-down resistor RN.

First PMOS transistors MZP₀, MZP₁, . . . , MZP₃₀ are coupled in parallel between power supply VCCQ and a first terminal of first pull-up resistor RZP, which has a second terminal coupled to first output terminal OUT₁. Each of first PMOS transistors MZP₀, MZP₁, . . . , MZP₃₀ has a width/length of W_{TPs1}/L_{TPs1}. First pull-up resistor RZP has a width/length of W_{RPs1}/L_{RPs1}.

Second PMOS transistors MP₀, MP₁, . . . , MP₃₀ are coupled in parallel between power supply VCCQ and a first terminal of second pull-up resistor RP, which has a second terminal coupled to second output terminal OUT₂. Each of second PMOS transistors MP₀, MP₁, . . . , MP₃₀ has a width/length of W_{TPs2}/L_{TPs2}. Second pull-up resistor RP has a width/length of W_{RPs2}/L_{RPs2}.

First NMOS transistors MN₀, MN₁, . . . , MN₃₀ are coupled in parallel between GROUND and a first terminal of pull-down resistor RN, which has a second terminal coupled to second output terminal OUT₂. Each of first NMOS transistors MN₀, MN₁, . . . , MN₃₀ has a width/length of W_{TNs}/L_{TNs}. Pull-down resistor RN has a width/length of W_{RNs}/L_{RNs}.

The width/length values for first PMOS transistors MZP₀, MZP₁, . . . , MZP₃₀, second PMOS transistors MP₀, MP₁, . . . , MP₃₀, first NMOS transistors MN₀, MN₁, . . . , MN₃₀, first pull-up resistor RZP, second pull-up resistor RP and pull-down resistor RN are:

$$\frac{{W}_{TPs 1}}{{L}_{TP}} = ( \frac{{W}_{TP}}{{L}_{TP}} ) \times Y 1$$

$$\frac{{W}_{RP}}{{L}_{RPs 1}} = \frac{( \frac{{W}_{RP}}{{L}_{RP}} )}{Y 1}$$

$$\frac{{W}_{TPs 2}}{{L}_{TP}} = ( \frac{{W}_{TP}}{{L}_{TP}} ) \times Y 2$$

$$\frac{{W}_{TNs}}{{L}_{TN}} = ( \frac{{W}_{TN}}{{L}_{TN}} ) \times Y 2$$

$$\frac{{W}_{RP}}{{L}_{RPs 2}} = \frac{( \frac{{W}_{RP}}{{L}_{RP}} )}{Y 2}$$

$$\frac{{W}_{RN}}{{L}_{RNs 2}} = \frac{( \frac{{W}_{RN}}{{L}_{RN}} )}{Y 2}$$

where W_{TP}/L_{TP}, W_{TN}/L_{TN}, W_{RP}/L_{RP} and W_{RN}/L_{RN} are nominal width/length values for first PMOS transistors MZP₀, MZP₁, . . . , MZP₃₀, second PMOS transistors MP₀, MP₁, . . . , MP₃₀, first NMOS transistors MN₀, MN₁, . . . , MN₃₀, first pull-up resistor RZP, second pull-up resistor RP and pull-down resistor RN, respectively, Y1=(2×R_{TT})/R_{REF}, where (2×R_{TT}) is a nominal target resistance for first PMOS transistors MZP₀, MZP₁, . . . , MZP₃₀ and first pull-up resistor RZP, and Y2=R_{TT2}/R_{REF}, where R_{TT2} is a nominal target resistance for second PMOS transistors MP₀, MP₁, . . . , MP₃₀, first NMOS transistors MN₀, MN₁, . . . , MN₃₀, pull-up resistor RP and pull-down resistor RN.

Accordingly, it can be seen that in one embodiment, an impedance calibration circuit is provided for off-chip driver/on-die termination circuits. The impedance calibration circuit includes a first circuit receiving first control signals, second control signals, a third control signal and a fourth control signal. The first circuit includes a plurality of first PMOS transistors coupled in parallel between a power supply terminal and a first output terminal, each of the first PMOS transistors coupled to a corresponding one of the first control signals; a plurality of second PMOS transistors coupled in parallel between the power supply terminal and a second output terminal, each of the second PMOS transistors coupled to a corresponding one of the first control signals; a plurality of first NMOS transistors coupled in parallel between the second output terminal and a GROUND terminal, each of the first NMOS transistors coupled to a corresponding one of the second control signals; a third PMOS transistor coupled in parallel with the plurality of first PMOS transistors between a power supply terminal and a first output terminal, and coupled to the third control signal; and a second NMOS transistor coupled in parallel with the plurality of first NMOS transistors between the second output terminal and a GROUND terminal, and coupled to the fourth control signal.

In another embodiment, an impedance calibration circuit is provided for off-chip driver/on-die termination circuits. The impedance calibration circuit includes a first circuit receiving first control signals and second control signals. The first circuit includes a plurality of first PMOS transistors coupled in parallel between a power supply terminal and a first terminal of a first resistor, each of the first PMOS transistors coupled to a corresponding one of the first control signals, the first terminal of the first resistor coupled to the first output terminal; a plurality of second PMOS transistors coupled in parallel between the power supply terminal and a first terminal of a second resistor, each of the second PMOS transistors coupled to a corresponding one of the first control signals, the second resistor including a second terminal coupled to the second output terminal; and a plurality of first NMOS transistors coupled in parallel between the second output terminal and a GROUND terminal, each of the first NMOS transistors coupled to a corresponding one of the second control signals.

In another embodiment, an impedance calibration circuit is provided for off-chip driver/on-die termination circuits. The impedance calibration circuit includes a first circuit receiving first control signals, second control signals, a third control signal and a fourth control signal. The first circuit includes a plurality of first PMOS transistors coupled in parallel between a power supply terminal and a first terminal of a first resistor, each of the first PMOS transistors coupled to a corresponding one of the first control signals, the first resistor comprising a second terminal coupled to the first output terminal; a plurality of second PMOS transistors coupled in parallel between the power supply terminal and a first terminal of a second resistor, each of the second PMOS transistors coupled to a corresponding one of the first control signals, the second resistor comprising a second terminal coupled to the second output terminal; a plurality of first NMOS transistors coupled in parallel between a first terminal of a third resistor and a GROUND terminal, each of the first NMOS transistors coupled to a corresponding one of the second control signals, the third resistor comprising a second terminal coupled to the second output terminal; a third PMOS transistor coupled in parallel with the plurality of first PMOS transistors between the power supply terminal and the first terminal of the first resistor, and coupled to the third control signal; and a second NMOS transistor coupled in parallel with the plurality of first NMOS transistors between the first terminal of the third resistor and the GROUND terminal, and coupled to the fourth control signal.

In another embodiment, an impedance calibration circuit is provided for off-chip driver/on-die termination circuits. The impedance calibration circuit includes a plurality of first circuits and a selector circuit configured to received process, temperature and power supply data and provide the enable signals to the plurality of first circuits. Each first circuit receives first control signals, second control signals, and a corresponding enable signal. Each of the first circuits includes a plurality of first PMOS transistors coupled in parallel between a power supply terminal and a first terminal of a first resistor, each of the first PMOS transistors coupled to a corresponding one of the first control signals, the first resistor including a second terminal coupled to the first output terminal; a plurality of second PMOS transistors coupled in parallel between the power supply terminal and a first terminal of a second resistor, each of the second PMOS transistors coupled to a corresponding one of the first control signals, the second resistor including a second terminal coupled to the second output terminal; and a plurality of first NMOS transistors coupled in parallel between a first terminal of a third resistor and a GROUND terminal, each of the first NMOS transistors coupled to a corresponding one of the second control signals, the third resistor including a second terminal coupled to the second output terminal.

In still another embodiment, an impedance calibration circuit is provided for off-chip driver/on-die termination circuits. The impedance calibration circuit includes a first circuit receiving first control signals and second control signals, a comparator including a first input terminal, a second input terminal, and an output terminal, and a selector circuit configured to received process, temperature and power supply data and provide one of a plurality of reference voltages to the second input terminal of the comparator. The first input terminal of the comparator is selectively coupled to the first output terminal and the second output terminal of the first circuit. The first circuit includes a plurality of first PMOS transistors coupled in parallel between a power supply terminal and a first terminal of a first resistor, each of the first PMOS transistors coupled to a corresponding one of the first control signals, the first resistor including a second terminal coupled to the first output terminal; a plurality of second PMOS transistors coupled in parallel between the power supply terminal and a first terminal of a second resistor, each of the second PMOS transistors coupled to a corresponding one of the first control signals, the second resistor including a second terminal coupled to the second output terminal; and a plurality of first NMOS transistors coupled in parallel between a first terminal of a third resistor and a GROUND terminal, each of the first NMOS transistors coupled to a corresponding one of the second control signals, the third resistor including a second terminal coupled to the second output terminal.

Corresponding methods, systems and computer- or processor-readable storage devices for performing the methods provided herein are provided.

The foregoing detailed description has been presented for purposes of illustration and description. It is not intended to be exhaustive or limited to the precise form disclosed. Many modifications and variations are possible in light of the above teaching. The described embodiments were chosen in order to best explain the principles of the technology and its practical application, to thereby enable others skilled in the art to best utilize the technology in various embodiments and with various modifications as are suited to the particular use contemplated. It is intended that the scope of the technology be defined by the claims appended hereto.

1-23. (canceled)

24. An impedance calibration circuit comprising:
a plurality of replica circuits, each of the replica circuits having a corresponding unique configuration; and
a selector circuit configured to select, based on one or more of process, temperature and power supply data, one of the replica circuits to match a reference impedance.

25. The impedance calibration circuit of claim 24, wherein the plurality of replica circuits each comprise off-chip driver replica circuits.

26. The impedance calibration circuit of claim 24, wherein the plurality of replica circuits each comprise on-die termination replica circuits.

27. The impedance calibration circuit of claim 24, wherein each of the plurality of replica circuits is configured to target a corresponding unique impedance.

28. The impedance calibration circuit of claim 24, wherein the plurality of replica circuits are configured to target a plurality of impedances.

29. The impedance calibration circuit of claim 24, wherein:
each of the plurality of replica circuits comprises a first output terminal and a second output terminal;
the first output terminal of each of the plurality of replica circuits are coupled together; and
the second output terminal of each of the plurality of replica circuits are coupled together.

30. The impedance calibration circuit of claim 24, wherein:
each of the plurality of replica circuits comprises a plurality of first transistors coupled in parallel and a plurality of second transistors coupled in parallel; and
each of the first transistors and each of the second transistors in each of the replica circuits has a corresponding unique width/length.

31. The impedance calibration circuit of claim 30, wherein:
each of the plurality of replica circuits further comprises a plurality of third transistors coupled in parallel; and
each of the third transistors in each of the replica circuits has a corresponding unique width/length.

32. The impedance calibration circuit of claim 24, wherein:
each of the plurality of replica circuits comprises a first resistor and a second resistor; and
each first resistor and each second resistor in each of the replica circuits has a corresponding unique width/length.

33. The impedance calibration circuit of claim 24, wherein the selector circuit comprises a lookup table.

34. A system comprising:
an input-output circuit; and
an impedance calibration circuit configured to control an impedance of the input-output circuit, the impedance calibration circuit comprising:
a plurality of replica circuits, each of the plurality of replica circuits configured to target a corresponding unique resistance; and
a selector circuit configured to select, based on one or more of process, temperature and power supply data, one of the replica circuits to match a reference impedance.

35. The system of claim 31, wherein the input-output circuit comprises an off-chip driver circuit.

36. The system of claim 34, wherein the input-output circuit comprises an on-die termination circuit.

37. The system of claim 34, wherein the plurality of replica circuits are configured to target a plurality of resistances.

38. The system of claim 34, wherein the system comprises a memory device comprising a memory die comprising the input-output circuit.

39. A method comprising:
providing a plurality of replica circuits;
configuring each of the replica circuits to target a corresponding unique impedance;
selecting, based on one or more of process, temperature and power supply data, one of the plurality of replica circuits; and
using the selected replica circuit to match a reference impedance.

40. The method of claim 39, wherein the plurality of replica circuits comprise each comprise off-chip driver replica circuits.

41. The method of claim 39, wherein the plurality of replica circuits comprise each comprise on-die termination replica circuits.

42. The method of claim 39, wherein each of the plurality of replica circuits comprises a first output terminal and a second output terminal, and the method further comprises:
coupling together the first output terminal of each of the plurality of replica circuits; and
coupling together the second output terminal of each of the plurality of replica circuits.

43. The method of claim 39, wherein:
each of the plurality of replica circuits comprises a plurality of first transistors coupled in parallel and a plurality of second transistors coupled in parallel; and
each of the first transistors and each of the second transistors in each of the replica circuits has a corresponding unique width/length.

44. The method of claim 43, wherein:
each of the plurality of replica circuits further comprises a plurality of third transistors coupled in parallel; and
each of the third transistors in each of the replica circuits has a corresponding unique width/length.

45. The method of claim 39, wherein:
each of the plurality of replica circuits comprises a first resistor and a second resistor; and
each first resistor and each second resistor in each of the replica circuits has a corresponding unique width/length.

46. The method of claim 39, wherein the selector circuit comprises a lookup table.
